(19) United States
(12) Patent Application Publication
(10) Pub. No.: US 2011/0062466 A1
(43) Pub. Date: Mar. 17, 2011

(54) AlxGa(1-x)As Substrate, Epitaxial Wafer for Infrared LEDs, Infrared LED, Method of Manufacturing AlxGa(1-x)As Substrate, Method of Manufacturing Epitaxial Wafer for Infrared LEDs, and Method of Manufacturing Infrared LEDs

(75) Inventors: So Tanaka, Itami-shi (JP); Kenichi Miyahara, Itami-shi (JP); Hiroyuki Kitabayashi, Osaka-shi (JP); Koji Katayama, Itami-shi (JP); Tomonori Morishita, Itami-shi (JP); Tatsuya Moriwake, Itami-shi (JP)

(73) Assignee: SUMITOMO ELECTRIC INDUSTRIES, LTD., Osaka (JP)

(21) Appl. No.: 12/921,152

(22) PCT Filed: May 27, 2009
(86) PCT No.: PCT/JP2009/059647

§ 371 Date: Sep. 3, 2010

(30) Foreign Application Priority Data
Jun. 3, 2008 (JP) 2008-146052
Apr. 17, 2009 (JP) 2009-101226

(51) Int. Cl. H01L 33/30; H01L 29/205; H01L 21/205

(52) U.S. Cl. 257/94; 257/615; 438/500; 438/47; 257/E33.027; 257/E21.109

(57) ABSTRACT

Affords AlₓGa₍₁₋ₓ₎As (0≦x≦1) substrates epitaxial wafers for infrared LEDs, infrared LEDs, methods of manufacturing AlₓGa₍₁₋ₓ₎As substrates, methods of manufacturing epitaxial wafers for infrared LEDs, and methods of manufacturing infrared LEDs, whereby a high level of transmissivity is maintained, and through which, in the fabrication of semiconductor devices, the devices prove to have superior light output characteristics. An AlₓGa₍₁₋ₓ₎As substrate (10a) as disclosed is an AlₓGa₍₁₋ₓ₎As substrate (10a) furnished with an AlₓGa₍₁₋ₓ₎As layer (11) having a major surface (11a) and, on the reverse side from the major surface (11a), a rear face (11b), and is characterized in that in the AlₓGa₍₁₋ₓ₎As layer (11), the amount fraction x of Al in the rear face (11b) is greater the amount fraction x of Al in the major surface (11a). The AlₓGa₍₁₋ₓ₎As substrate (10a) may additionally be provided with a GaAs substrate (13), contacting the rear face (11b) of the AlₓGa₍₁₋ₓ₎As layer (11).

### TECHNICAL FIELD

The present invention relates to AlₓGa₍₁₋ₓ₎As substrates, to epitaxial wafers for infrared LEDs, to infrared LEDs, to methods of manufacturing AlₓGa₍₁₋ₓ₎As substrates, to methods of manufacturing epitaxial wafers for infrared LEDs, and to methods of manufacturing infrared LEDs.

### BACKGROUND ART

LEDs (light-emitting diodes) exploiting the compound semiconductor AlₓGa₍₁₋ₓ₎As (0≦x≦1)—hereinafter also termed “AlGaAs,” (aluminum gallium arsenide)—are widely employed as infrared light sources. Infrared LEDs are used as infrared light sources in such applications as optical communications and wireless transmission, and in these applications the stepping-up of transmitted data volume and enabling of longer-range transmission distances that are taking place have led to demands for improved output power from infrared LEDs.

An example of a method of manufacturing such infrared LEDs is disclosed in Japanese Unexamined Pat. App. Pub. No. 2002-335008 (Patent Reference 1). The implementation of the following process steps is set forth in this patent reference. Namely, to begin with an AlₓGa₍₁₋ₓ₎As support substrate is formed onto a GaAs (gallium arsenide) substrate by liquid-phase epitaxy (LPE). At that point, the amount fraction of Al (aluminum) in the AlₓGa₍₁₋ₓ₎As support substrate is approximately uniform. Subsequently, epitaxial layers are formed by organometallic vapor-phase epitaxy (OMVPE) or molecular beam epitaxy (MBE).

### CITATION LIST

### Patent Literature

Patent Literature 1: Japanese Unexamined Pat. App. Pub. No. 2002-335008

### SUMMARY OF INVENTION

### Technical Problem

In the above-noted Patent Reference 1, the amount fraction of Al in the AlₓGa₍₁₋ₓ₎As support substrate is for the most part uniform. As a result of dedicated research efforts, the present inventors discovered a problem with instances in which the Al amount fraction is high, in that the properties of infrared LEDs manufactured employing such AlₓGa₍₁₋ₓ₎As support substrates deteriorate. As a further result of their dedicated research efforts, the present inventors also discovered a problem with instances in which the Al amount fraction is low, in that the transmissivity of such AlₓGa₍₁₋ₓ₎As support substrates is poor.

Therein, an object of the present invention is to make available AlₓGa₍₁₋ₓ₎As substrates, epitaxial wafers for infrared LEDs, infrared LEDs, methods of manufacturing AlₓGa₍₁₋ₓ₎As substrates, methods of manufacturing epitaxial wafers for infrared LEDs, and methods of manufacturing infrared LEDs, whereby a high level of transmissivity is maintained, and through which, in the fabrication of semiconductor devices, the devices prove to have superior characteristics.

### Solution to Problem

As a result of their especially focused research efforts, the present inventors not only found that the properties of infrared LEDs manufactured employing the AlₓGa₍₁₋ₓ₎As support substrates are compromised when the Al amount fraction is high, but they also discovered the cause of the problem. Namely, aluminum has a propensity to oxidize readily, on account of which an oxide layer is liable to form on the surface of an AlₓGa₍₁₋ₓ₎As substrate. Since the oxide layer impairs epitaxial layers grown onto the AlₓGa₍₁₋ₓ₎As substrate, it proves to be a causative factor whereby defects are introduced into the epitaxial layers. The problem with defects introduced into epitaxial layers is that they are deleterious to the properties infrared LEDs comprising the epitaxial layers.

Meanwhile, the present inventor's research efforts also led them to discover that the transmissivity of AlₓGa₍₁₋ₓ₎As substrates worsens the lower is the substrates' amount fraction of Al.

Therein, an AlₓGa₍₁₋ₓ₎As substrate of the present invention is an AlₓGa₍₁₋ₓ₎As substrate furnished with an AlₓGa₍₁₋ₓ₎As layer (0≦x≦1) having a major surface and, on the reverse side from the major surface, a rear face, and is characterized in that in the AlₓGa₍₁₋ₓ₎As layer, the amount fraction x of Al in the rear face is greater than the amount fraction x of Al in the major surface.

In the just-described AlₓGa₍₁₋ₓ₎As substrate, the AlₓGa₍₁₋ₓ₎As layer preferably contains a plurality of laminae, and the amount fraction x of Al in each of the plural laminae monotonically decreases heading from the plane of the layer's rear-face side to the plane of its major-surface side.

For the just-described AlₓGa₍₁₋ₓ₎As substrate, a GaAs substrate preferably is further furnished, contacting the rear face of the AlₓGa₍₁₋ₓ₎As layer.

An epitaxial wafer of the present invention for infrared LEDs is furnished with an AlₓGa₍₁₋ₓ₎As substrate as set forth in any of the foregoing descriptions, and an epitaxial layer formed onto the major surface of the AlₓGa₍₁₋ₓ₎As layer, and including an active layer.

In the infrared-LED epitaxial wafer just described, preferably the amount fraction x of Al in the plane of epitaxial layer contact with the AlₓGa₍₁₋ₓ₎As layer is greater than the amount fraction x of Al in the plane of AlₓGa₍₁₋ₓ₎As layer contact with the epitaxial layer.

With an aforementioned epitaxial wafer for infrared LEDs, preferably the epitaxial wafer is utilized in an infrared LED whose emission wavelength is 900 nm or greater, and the well layers within the active layer include a material containing indium (In), with the well layers being four or fewer laminae.

In the infrared-LED epitaxial wafer described above, preferably the well layers are of InGaAs in which the amount fraction of indium is 0.05 or more.

With an aforementioned epitaxial wafer for infrared LEDs, preferably the epitaxial wafer is utilized in an infrared LED whose emission wavelength is 900 nm or greater, and the barrier layers within the active layer include a material containing phosphorous (P), with the barrier layers being three or more laminae.

In the infrared-LED epitaxial wafer described above, preferably the barrier layers are of either GaAsP or AlGaAsP in which the amount fraction of phosphorous is 0.05 or more.

An infrared LED of the present invention is furnished with: an AlₓGa₍₁₋ₓ₎As substrate set forth in any of the foregoing descriptions; an epitaxial layer; a first electrode; and a second electrode. The epitaxial layer is formed onto the major surface of the AlₓGa₍₁₋ₓ₎As layer, and includes an active layer. The first electrode is formed on the surface of the epitaxial layer. The second electrode is formed on the rear face of the AlₓGa₍₁₋ₓ₎As layer. In AlₓGa₍₁₋ₓ₎As substrates of a form furnished with a GaAs substrate, the second electrode may be formed on the rear face of the GaAs substrate.

An AlₓGa₍₁₋ₓ₎As substrate manufacturing method of the present invention is provided with a step of preparing a GaAs substrate, and a step of growing, by liquid-phase epitaxy, onto the GaAs substrate an AlₓGa₍₁₋ₓ₎As layer (0≦x≦1) having a major surface. Then, in the step of growing a AlₓGa₍₁₋ₓ₎As layer, the AlₓGa₍₁₋ₓ₎As layer is grown with the amount fraction x of Al in the interface between the layer and the GaAs substrate being greater than the amount fraction x of Al in the major surface.

With the AlₓGa₍₁₋ₓ₎As substrate manufacturing method described above, in the AlₓGa₍₁₋ₓ₎As layer growing step, preferably the AlₓGa₍₁₋ₓ₎As layer is grown containing a plurality of laminae in which the amount fraction x of Al monotonically decreases heading from the plane along the layer's interface with the GaAs substrate to the plane of the layer's major-surface side.

With the AlₓGa₍₁₋ₓ₎As substrate manufacturing method described above, preferably a step of removing the GaAs substrate is further provided.

A method of the present invention of manufacturing an epitaxial wafer for infrared LEDs is provided with: a step of manufacturing an AlₓGa₍₁₋ₓ₎As substrate by an AlₓGa₍₁₋ₓ₎As substrate manufacturing method set forth in any of the foregoing descriptions; and a step of forming onto the major surface of the AlₓGa₍₁₋ₓ₎As layer, by at least organometallic vapor-phase epitaxy or molecular beam epitaxy, or else by a combination of the two techniques, an epitaxial layer containing an active layer.

With the infrared-LED epitaxial wafer manufacturing method described above, preferably the amount fraction x of Al in the plane of epitaxial layer contact with the AlₓGa₍₁₋ₓ₎As layer is greater than the amount fraction x of Al in the plane of AlₓGa₍₁₋ₓ₎As layer contact with the epitaxial layer.

With the aforementioned method of manufacturing an epitaxial wafer for infrared LEDs, preferably the method is of manufacturing an epitaxial wafer utilized in infrared LEDs whose emission wavelength is 900 nm or more, and the well layers within the active layer include a material that contains indium (In), with the number of well layers being four laminae or fewer.

With the infrared-LED epitaxial wafer manufacturing method described above, preferably the well layers are of InGaAs whose amount fraction of indium is 0.05 or more.

With the aforementioned method of manufacturing an epitaxial wafer for infrared LEDs, preferably the method is of manufacturing an epitaxial wafer utilized in infrared LEDs whose emission wavelength is 900 nm or more, and the barrier layers within the active layer include a material that contains phosphorous (P), with the number of barrier layers being three laminae or more.

With the infrared-LED epitaxial wafer manufacturing method described above, preferably the barrier layers are of either GaAsP or AlGaAsP whose amount fraction of phosphorous is 0.05 or more.

An infrared-LED manufacturing method of the present invention is provided with: a step of manufacturing an AlₓGa₍₁₋ₓ₎As substrate by an AlₓGa₍₁₋ₓ₎As substrate manufacturing method as set forth in any of the foregoing descriptions; a step of forming onto the major surface of the AlₓGa₍₁₋ₓ₎As layer, by either organometallic vapor-phase epitaxy or molecular beam epitaxy, an epitaxial layer containing an active layer; a step of forming a first electrode on the surface of the epitaxial layer; and a step of forming a second electrode on either the rear face of the AlₓGa₍₁₋ₓ₎As layer, or the rear face of the GaAs substrate (in AlₓGa₍₁₋ₓ₎As substrates of a form furnished with a GaAs substrate).

### ADVANTAGEOUS EFFECTS OF INVENTION

In accordance with AlₓGa₍₁₋ₓ₎As substrates, epitaxial wafers for infrared LEDs, infrared LEDs, methods of manufacturing AlₓGa₍₁₋ₓ₎As substrates, methods of manufacturing epitaxial wafers for infrared LEDs, and methods of manufacturing infrared LEDs of the present invention, a high level of transmissivity is maintained, and in the fabrication of semiconductor devices, lead to devices having superior characteristics.

### BRIEF DESCRIPTION OF DRAWINGS

FIG. 1 is a sectional diagram illustratively outlining an AlₓGa₍₁₋ₓ₎As substrate in Embodying Mode 1 of the present invention.

FIG. 2 is a chart for explaining the amount fraction x of Al in an AlₓGa₍₁₋ₓ₎As layer in Embodying Mode 1 of the present invention.

FIG. 3 is a chart for explaining the amount fraction x of Al in an AlₓGa₍₁₋ₓ₎As layer in Embodying Mode 1 of the present invention.

FIG. 4 is a chart for explaining the amount fraction x of Al in an AlₓGa₍₁₋ₓ₎As layer in Embodying Mode 1 of the present invention.

FIGS. 5 (A) through (G) are charts for explaining the amount fraction x of Al in an AlₓGa₍₁₋ₓ₎As layer in Embodying Mode 1 of the present invention.

FIG. 6 is a flowchart representing a method of manufacturing an AlₓGa₍₁₋ₓ₎As substrate in Embodying Mode 1 of the present invention.

FIG. 7 is a sectional diagram illustratively outlining a GaAs substrate in Embodying Mode 1 of the present invention.

FIG. 8 is a sectional diagram illustratively outlining an as-grown AlₓGa₍₁₋ₓ₎As layer in Embodying Mode 1 of the present invention.

FIGS. 9 (A) through (C) are charts for explaining the effect, in Embodying Mode 1 of the present invention, of furnishing an AlₓGa₍₁₋ₓ₎As layer with a plurality of lamina in which the amount fraction x of Al monotonically decreases.

FIG. 10 is a sectional diagram illustratively outlining an AlₓGa₍₁₋ₓ₎As substrate in Embodying Mode 2 of the present invention.

FIG. 11 is a flowchart representing a method of manufacturing an AlₓGa₍₁₋ₓ₎As substrate in Embodying Mode 2 of the present invention.

FIG. 12 is a sectional diagram illustratively outlining an infrared-LED epitaxial wafer in Embodying Mode 3 of the present invention.

FIG. 13 is a sectional diagram that is an enlargement of the region XIII in FIG. 12.

FIG. 14 is a flowchart representing a method of manufacturing an infrared-LED epitaxial wafer in Embodying Mode 3 of the present invention.

FIG. 15 is a sectional diagram illustratively outlining an infrared-LED epitaxial wafer in Embodying Mode 4 of the present invention.

FIG. 16 is a flowchart representing a method of manufacturing an epitaxial wafer in Embodying Mode 4 of the present invention.

FIG. 17 is a sectional diagram illustratively outlining an infrared-LED epitaxial wafer in Embodying Mode 5 of the present invention.

FIG. 18 is a sectional diagram illustratively outlining an infrared LED in Embodying Mode 6 of the present invention.

FIG. 19 is a flowchart representing a method of manufacturing an infrared LED in Embodying Mode 6 of the present invention.

FIG. 20 is a sectional diagram illustratively outlining an infrared LED in Embodying Mode 7 of the present invention.

FIG. 21 is a graph plotting transmissivity versus amount fraction x of Al in AlₓGa₍₁₋ₓ₎As layers of Embodiment 1.

FIG. 22 is a graph plotting surface oxygen quantity versus amount fraction x of Al in AlₓGa₍₁₋ₓ₎As layers of Embodiment 1.

FIG. 23 is a sectional diagram illustratively outlining an infrared-LED epitaxial wafer in Embodiment 3.

FIG. 24 is a chart diagramming light output, in Embodiment 3, from an infrared-LED epitaxial wafer furnished with an active layer having multiquantum-well structures, and from an epitaxial wafer for double-heterostructure infrared LEDs.

FIG. 25 is a sectional diagram illustratively outlining an infrared-LED epitaxial wafer in Embodiment 4.

FIG. 26 is a chart diagramming the relationship between window-layer thickness and light output power in Embodiment 4.

FIG. 27 is a sectional diagram illustratively outlining an infrared LED in a modified example of Embodying Mode 7 of the present invention.

FIG. 28 is a chart plotting results of measuring the emission wavelength from an infrared LED in Embodiment 6.

### DESCRIPTION OF EMBODIMENTS

In the following, an explanation based on the drawings will be made of modes of embodying the present invention.

### Embodying Mode 1

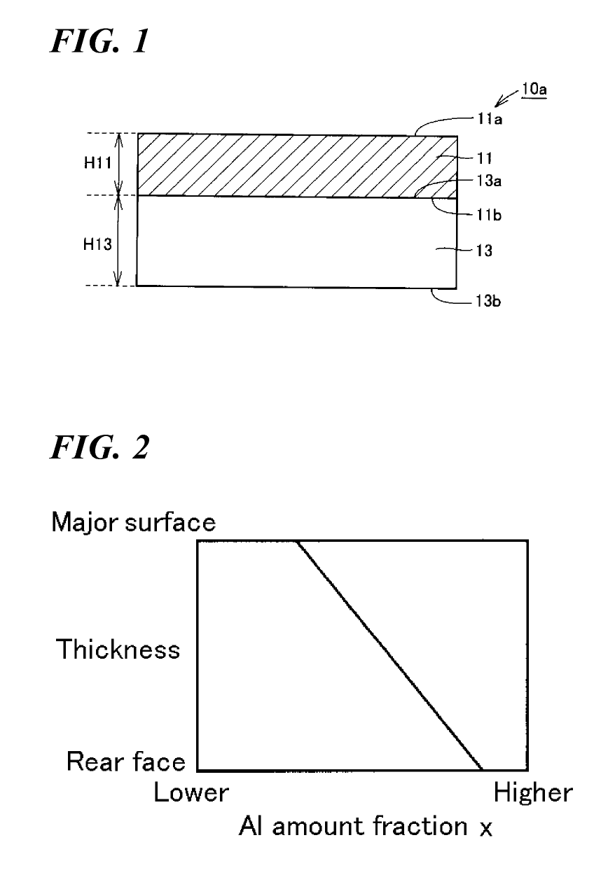

To begin with, referring to FIG. 1, an explanation of an AlₓGa₍₁₋ₓ₎As substrate in the present embodying mode will be made.

As represented in FIG. 1, an AlₓGa₍₁₋ₓ₎As substrate 10a is furnished with a GaAs substrate 13, and an AlₓGa₍₁₋ₓ₎As layer 11 formed onto the GaAs substrate 13.

The GaAs substrate 13 has a major surface 13a, and a rear face 13b on the reverse side from the major surface 13a. The AlₓGa₍₁₋ₓ₎As layer 11 has a major surface 11a, and a rear face 11b on the reverse side from the major surface 11a.

The GaAs substrate 13 may or may not be misoriented—for example, the substrate may have a major surface 13a that is a {100} plane, or that is tilted more than 0° but 15.8° or less from a {100} plane. It is preferable that the GaAs substrate 13 have a major surface 13a that is a {100} plane, or that is tilted more than 0° but 2° or less from a {100} plane. It is further preferable that the GaAs substrate 13 have a surface that is a {100} plane, or that is tilted more than 0° but 0.2° or less from a {100} plane. The GaAs substrate 13 surface may be a specular surface, or may be a rough surface. (It will be understood that the braces “{ }” indicate a family of planes.)

The AlₓGa₍₁₋ₓ₎As layer 11 has a major surface 11a and, on the reverse side from the major surface 11a, a rear face 11b. The major surface 11a is the surface on the reverse side from the surface that contacts the GaAs substrate 13. The rear face 11b is the surface that contacts the GaAs substrate 13.

The AlₓGa₍₁₋ₓ₎As layer 11 is formed so as to contact on the major surface 13a of the GaAs substrate 13. Put differently, the GaAs substrate 13 is formed as to contact on the rear face 11b of the AlₓGa₍₁₋ₓ₎As layer 11.

In the AlₓGa₍₁₋ₓ₎As layer 11, the amount fraction x of Al in the rear face 11b is greater than the amount fraction x of Al in the major surface 11a. It should be understood that the amount fraction x is the mole fraction of Al, while the amount fraction (1−x) is the mole fraction of Ga.

Therein, the mole fraction in the AlₓGa₍₁₋ₓ₎As layer 11 will be explained with reference to FIGS. 2 through 5.

In FIGS. 2 through 5, the vertical axis indicates position thickness-wise traversing from the rear face to the major surface of the AlₓGa₍₁₋ₓ₎As layer 11, while the horizontal axis represents the Al amount fraction x in each position.

As shown in FIG. 2, with the AlₓGa₍₁₋ₓ₎As layer 11, traversing from the rear face 11b to the major surface 11a, the amount fraction x of Al monotonically decreases. “Monotonically decreases” means that heading from the rear face 11b to the major surface 11a of the AlₓGa₍₁₋ₓ₎As layer 11 (heading in the growth direction), the amount fraction x is constantly the same or decreasing, and that, compared with the rear face 11b, the major surface 11a is where the amount fraction x is lower.

Put differently, “monotonically decreases” would not include a section in which the amount fraction x increases heading in the growth direction.

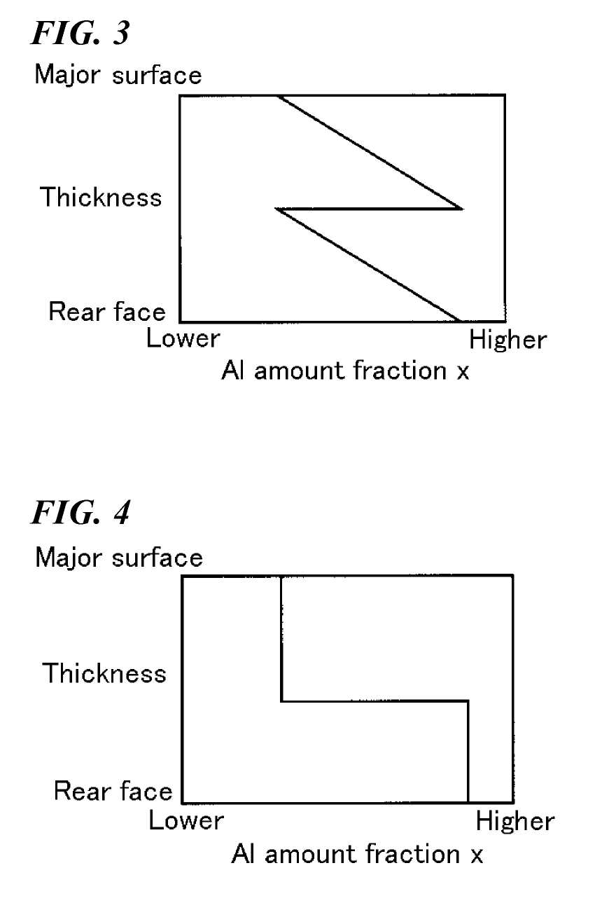

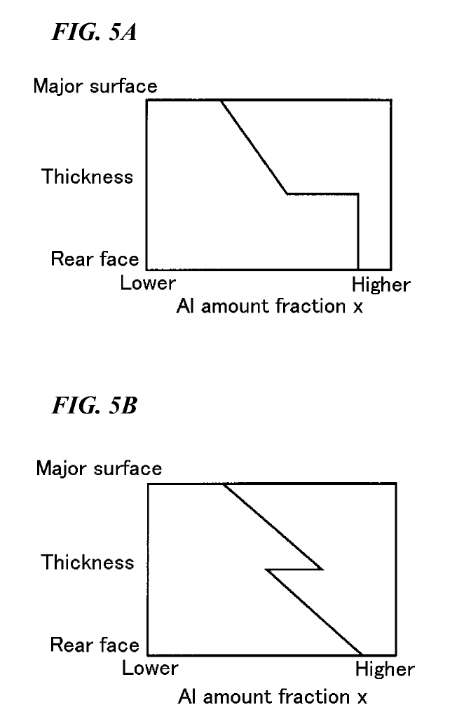

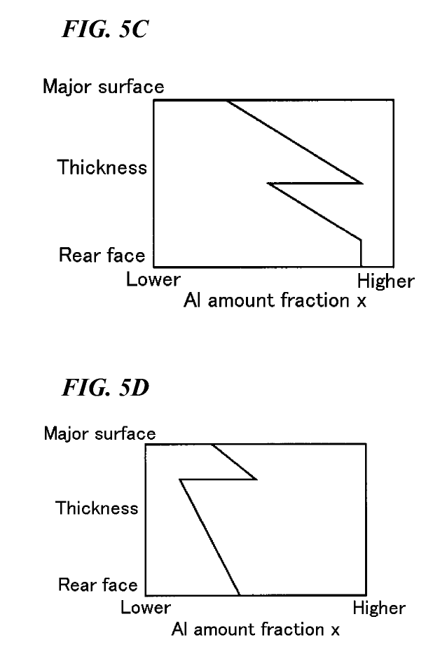

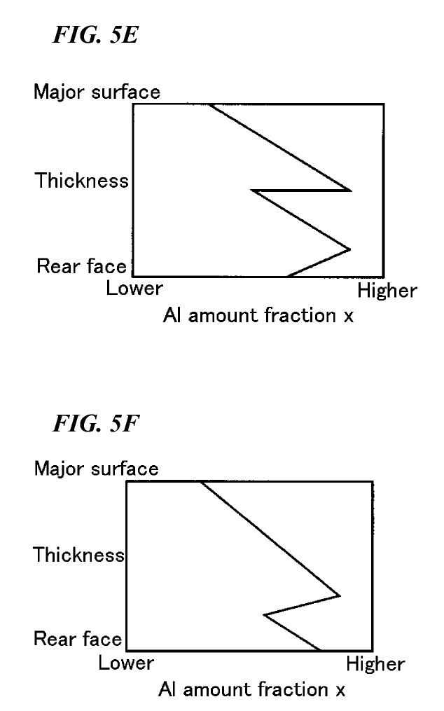

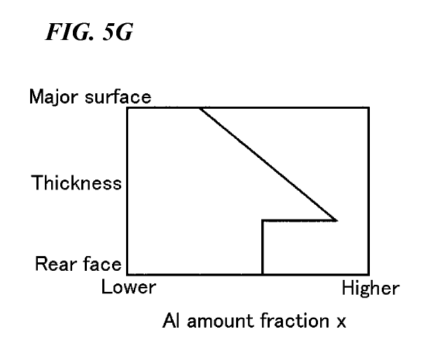

As indicated in FIGS. 3 through 5, the AlₓGa₍₁₋ₓ₎As layer 11 may include a plurality of laminae (in FIGS. 3 through 5, it includes two laminae). With the AlₓGa₍₁₋ₓ₎As layer 11 represented in FIG. 3, traversing in each lamina from the rear face 11b side to the major surface 11a side, the amount fraction x of Al monotonically decreases. Meanwhile, with the AlₓGa₍₁₋ₓ₎As layer 11 represented in FIG. 4, the amount fraction x of Al is uniform in each lamina, but the amount fraction x of Al in the lamina along the rear face 11b is greater than in that along the major surface 11a. On the other hand, the amount fraction x of Al in the lamina along the rear face 11b of the AlₓGa₍₁₋ₓ₎As layer 11 represented in FIG. 5(A) is uniform, while the amount fraction x of Al in the lamina along the major surface 11a monotonically decreases, with the Al amount fraction x in the lamina along the rear face 11b being greater than in that along the major surface 11a. In sum, with the AlₓGa₍₁₋ₓ₎As layers 11 represented in FIGS. 4 and 5(A), as a whole, the amount fraction x of Al monotonically decreases.

It should be understood that the amount fraction x of Al in the AlₓGa₍₁₋ₓ₎As layer 11 is not limited to the foregoing, and the composition may be as indicated for example in FIGS. 5(B) through (G), or further may be a separate example. Also, the AlₓGa₍₁₋ₓ₎As layer 11 is not limited to the above-described implementations containing one lamina or two laminae, but may contain three or more laminae, as long as the amount fraction x of Al in the rear face 11b is greater than the amount fraction x of Al in the major surface 11a.

When the AlₓGa₍₁₋ₓ₎As substrate 10a is utilized in an LED, the AlₓGa₍₁₋ₓ₎As layer 11 assumes, for example, the role of a window layer that diffuses current and that transmits light from the active layer.

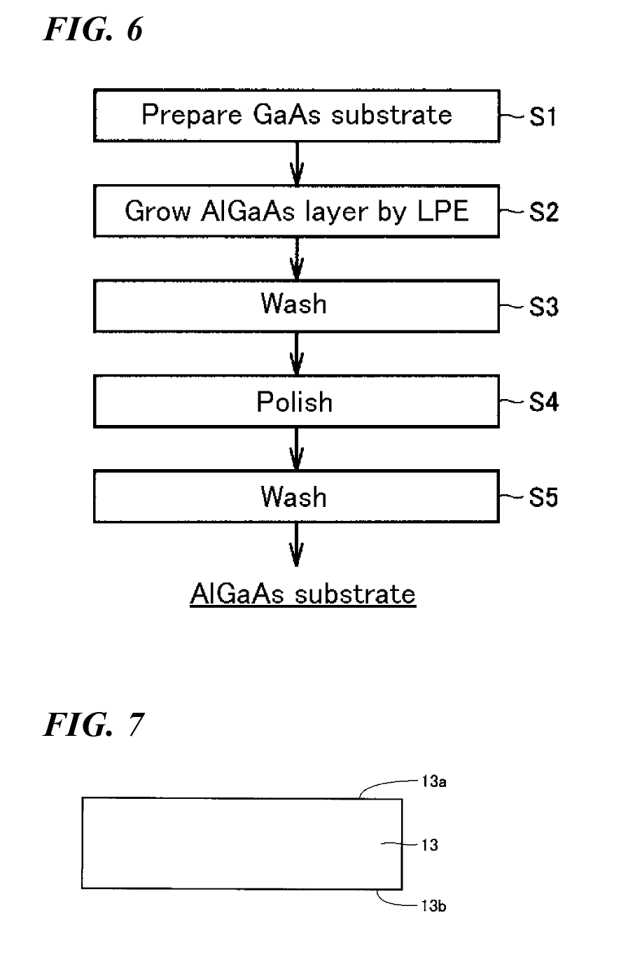

To continue: With reference to FIG. 6, an explanation of a method of manufacturing an AlₓGa₍₁₋ₓ₎As substrate in the present embodying mode will be made.

As indicated in FIGS. 6 and 7, initially a GaAs substrate 13 is prepared (Step S1).

The GaAs substrate 13 may or may not be misoriented—for example, the substrate may have a major surface 13a that is a {100} plane, or that is tilted more than 0° but 15.8° or less from a {100} plane. It is preferable that the GaAs substrate 13 have a major surface 13a that is a {100} plane, or that is tilted more than 0° but 2° or less from a {100} plane. It is further preferable that the GaAs substrate 13 have a major surface 13a that is a {100} plane, or that is tilted more than 0° but 0.2° or less from a {100} plane.

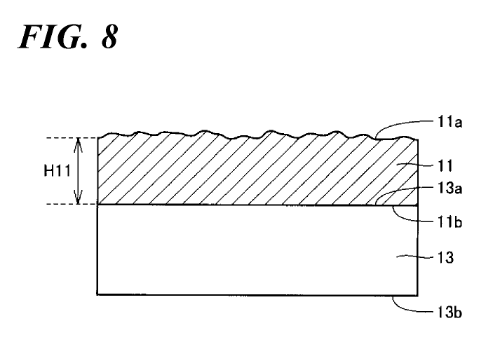

As indicated in FIGS. 6 and 8, next an AlₓGa₍₁₋ₓ₎As layer (0≦x≦1) 11 having a major surface 11a is grown by liquid-phase epitaxy onto the GaAs substrate 13 (Step S2). By Step S2 of growing the AlₓGa₍₁₋ₓ₎As layer 11, an AlₓGa₍₁₋ₓ₎As layer 11 in which the amount fraction x of Al in the layer's interface with the GaAs substrate 13 (the rear face 11b) is greater than the amount fraction x of Al in the major surface 11a is grown.

The liquid-phase epitaxy is not particularly limited; a slow-cooling or temperature-profile technique can be employed. It should be understood that “liquid-phase epitaxy” refers to a technique of growing the AlₓGa₍₁₋ₓ₎As (0≦x≦1) crystal from the liquid phase. A “slow-cooling” technique is a method of gradually lowering the temperature of a source-material solution to grow the AlₓGa₍₁₋ₓ₎As crystal. A “temperature-profile” technique refers to a method of setting up a temperature gradient in a source-material solution to grow the AlₓGa₍₁₋ₓ₎As crystal.

When a lamina in which the amount fraction x of Al in the AlₓGa₍₁₋ₓ₎As layer 11 is fixed is to be grown, temperature-profile and slow-cooling techniques are preferably utilized, while when a lamina in which the amount fraction x of Al decreases heading upward (in the growth direction) is to be grown, slow-cooling is preferably utilized. Utilizing slow cooling, owing to its superior volume produciblity and low cost, is particularly preferable. These techniques also may be combined.

With LPE, since a chemical equilibrium between the liquid and solid phases is exploited, the growth rate is rapid. On that account, an AlₓGa₍₁₋ₓ₎As layer 11 of considerable thickness may be readily formed. Specifically, an AlₓGa₍₁₋ₓ₎As layer 11 having a height H11 preferably of from 10 μm to 1000 μm, more preferably from 20 μm to 140 μm is grown. (In so doing, the height H11 is the minimum thickness along the AlₓGa₍₁₋ₓ₎As layer 11 thickness-wise.)

A further preferable condition is that the ratio of the height H11 of the AlₓGa₍₁₋ₓ₎As layer 11 to the height H13 of the GaAs substrate 13 (H11/H13) be from 0.1 to 0.5, more preferably from 0.3 to 0.5. This conditional factor makes it possible to mitigate the incidence of warp in the AlₓGa₍₁₋ₓ₎As layer 11 having been grown onto the GaAs substrate 13.

Furthermore, the AlₓGa₍₁₋ₓ₎As layer 11 may be grown so as to incorporate p-type dopants such as zinc (Zn), magnesium (Mg) and carbon (C), and n-type dopants such as selenium (Se), sulfur (S) and tellurium (Te), for example.

In this way growing an AlₓGa₍₁₋ₓ₎As layer 11 by LPE produces a jaggedness in the major surface 11a of the AlₓGa₍₁₋ₓ₎As layer 11, as indicated in FIG. 8.

Next, the major surface 11a of the AlₓGa₍₁₋ₓ₎As layer 11 is washed (Step S3). In Step S3, washing is preferably done using an alkali solution. However, an oxidizing solution such as phosphoric acid or sulfuric acid may also be employed. The alkali solution preferably contains ammonia and hydrogen peroxide. Washing the major surface 11a with an alkali solution containing ammonia and hydrogen peroxide etches the surface, which by the surface being in contact with air allows impurities clinging to the major surface 11a to be removed. By controlling the process so that, for example, with an etching rate of 0.2 μm/min or less, not more than 0.2 μm is etched from the major surface 11a side, impurities on the major surface 11a are reduced and at the same time the extent of etching will be slight. It should be noted that Step S3 of washing the major surface 11a may be omitted.

Next, the GaAs substrate 13 and the AlₓGa₍₁₋ₓ₎As layer 11 are dried with alcohol. This step of drying may be omitted, however.

Next, the major surface 11a of the AlₓGa₍₁₋ₓ₎As layer 11 is polished (Step S4). The method of polishing is not particularly limited; mechanical polishing, chemical-mechanical polishing, electrolytic polishing, or chemical polishing techniques may be employed, while in terms of polishing ease, mechanical polishing or chemical polishing are preferable.

The major surface 11a is polished so that the RMS roughness of the major surface 11a will be, for example, 0.05 nm or less. The RMS surface roughness is preferably minimal. Here, “RMS roughness” signifies a surface's mean-square roughness, as defined by JIS B0601—that is, the square root of the averaged value of the squares of the distance (deviation) from an averaging plane to a measuring plane. It should be noted that this polishing Step S4 may be omitted.

Next, the major surface 11a of the AlₓGa₍₁₋ₓ₎As layer 11 is washed (Step S5). Inasmuch as this Step 5 of washing the major surface 11a is the same as Step 3 of washing the major surface 11a prior to implementing polishing Step 4, explanation of the step will not be repeated. It should be noted that this washing Step S5 may be omitted.

Next, the GaAs substrate 13 and the AlₓGa₍₁₋ₓ₎As layer 11 are, by utilizing the AlₓGa₍₁₋ₓ₎As substrate 10a, thermally cleaned in an H₂ (hydrogen) and AsH₃ (arsine) flow prior to epitaxial growth. It should be understood that this thermal cleaning step may be omitted.

Implementing the foregoing Steps S1 through S5 enables the manufacture of an AlₓGa₍₁₋ₓ₎As substrate 10a in the present embodying mode, represented in FIG. 1.

As described in the foregoing, an AlₓGa₍₁₋ₓ₎As substrate 10a in the present embodying mode is an AlₓGa₍₁₋ₓ₎As substrate 10a furnished with an AlₓGa₍₁₋ₓ₎As layer 11 having a major surface 11a and, on the reverse side from the major surface 11a, a rear face 11b, and is characterized in that in the AlₓGa₍₁₋ₓ₎As layer 11, the amount fraction x of Al in the rear face 11b is greater than the amount fraction x of Al in the major surface 11a. Then further to this constitution a GaAs substrate 13 is provided, contacting the rear face 11b of the AlₓGa₍₁₋ₓ₎As layer 11.

In addition, a method of manufacturing an AlₓGa₍₁₋ₓ₎As substrate 10a in the present embodying mode is provided with a step (Step S1) of preparing a GaAs substrate 13, and a step (Step S2) of growing, by liquid-phase epitaxy, an AlₓGa₍₁₋ₓ₎As layer 11 having a major surface 11a onto the GaAs substrate 13. The method is characterized in that in the step of growing the AlₓGa₍₁₋ₓ₎As layer 11 (Step S2), an AlₓGa₍₁₋ₓ₎As layer 11 is grown in which the amount fraction x of Al in the interface between the layer and the GaAs substrate 13 (in the rear face 11b) is greater than the amount fraction x of Al in the major surface 11a.

According to an AlₓGa₍₁₋ₓ₎As substrate 10a and a method of manufacturing an AlₓGa₍₁₋ₓ₎As substrate 10a in the present embodying mode, the amount fraction x of Al in the rear face 11b is greater than the amount fraction x of Al in the major surface 11a. Therefore, the presence of aluminum, which has a propensity to oxidize, on the surface of the major surface 11a is kept to a minimum. And therefore, the formation of an oxide layer, which would act as an insulator, on the surface of the AlₓGa₍₁₋ₓ₎As substrate 10a (the major surface 11a of the AlₓGa₍₁₋ₓ₎As layer 11 in the present embodying mode) can be restrained.

Especially since the AlₓGa₍₁₋ₓ₎As layer 11 is grown by LPE, oxygen is unlikely to be taken into the layer-internal region, apart from the major surface 11a. Accordingly, when epitaxial layers are grown onto the AlₓGa₍₁₋ₓ₎As substrate 10a, defects can be kept from being introduced into the epitaxial layers. The characteristics of an infrared LED furnished with the epitaxial layers can be improved as a result.

As has been noted, the Al amount fraction x in the major surface 11a is less than the Al amount fraction x in the rear face 11b. The present inventor's intensive research efforts led them to discover that the greater the amount fraction x of Al is, the better will the transmissivity of the AlₓGa₍₁₋ₓ₎As substrate 10a be. And even if the layer contains much aluminum along the rear face 11b, because the period of time it is exposed on the surface is short, formation of any oxide layer is minimized. Consequently, growing AlₓGa₍₁₋ₓ₎As crystal of higher Al amount fraction x onto an area where oxide-layer formation is minimized allows the transmissivity to be improved.

In this way, in the AlₓGa₍₁₋ₓ₎As layer 11, the amount fraction x of Al is made lower along the major surface 11a so as to improve the device characteristics, while the amount fraction x of Al along the rear face 11b is made higher so as to improve the transmissivity. Hence, an AlₓGa₍₁₋ₓ₎As substrate 10a can be realized whereby a high level of transparency is maintained, and with which, when devices fabricated, the devices prove to have superior characteristics.

In the AlₓGa₍₁₋ₓ₎As substrate 10a described above, preferably, as indicated in FIG. 3, the AlₓGa₍₁₋ₓ₎As layer 11 contains a plurality of laminae, and the Al amount fraction x in each lamina monotonically decreases heading from the plane of the rear face 11b side to the plane of the major surface 11a side.

In the AlₓGa₍₁₋ₓ₎As substrate 10a manufacturing method described above, preferably, in the step of growing the AlₓGa₍₁₋ₓ₎As layer 11 (Step S2), preferably an AlₓGa₍₁₋ₓ₎As layer 11 is grown that contains a plurality of laminae in which the amount fraction x of Al monotonically decreases heading from the plane along the layer's interface with the GaAs substrate 13 (from the rear face 11b) to the plane of the layer's major-surface 11a side.

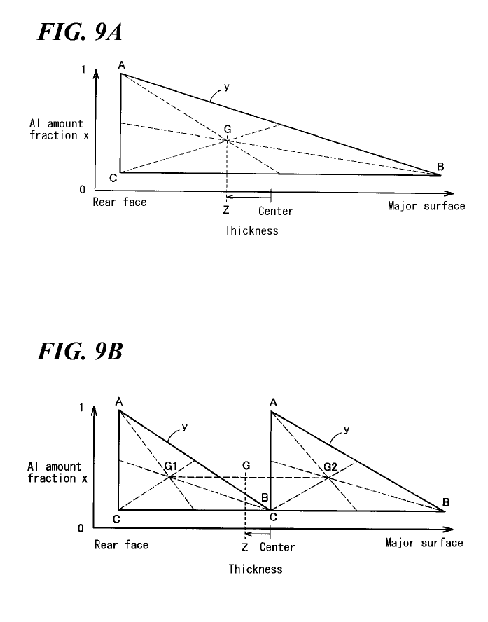

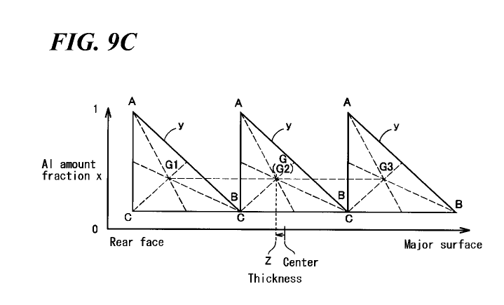

The present inventors discovered that thus constituting an AlₓGa₍₁₋ₓ₎As substrate 10a makes it possible to mitigate warp occurring in the substrate. Below, with reference to FIGS. 9(A) through (C), an explanation will be made of the reasons this is so. FIG. 9(A) represents an instance, as indicated in FIG. 2, where the laminar section in which the Al amount fraction x in the AlₓGa₍₁₋ₓ₎As layer 11 monotonically decreases is a single lamina. FIG. 9(B) represents an instance where in the AlₓGa₍₁₋ₓ₎As layer 11 the laminar section in which the Al amount fraction x monotonically decreases as indicated in FIG. 3 is two laminae. FIG. 9(C) represents an instance where the laminar section in which the Al amount fraction x monotonically decreases in the AlₓGa₍₁₋ₓ₎As layer 11 is three laminae. In FIGS. 9(A) through (C) the horizontal axis indicates position thickness-wise traversing from the rear face 11b to the major surface 11a of the AlₓGa₍₁₋ₓ₎As layer 11, while the vertical axis represents the Al amount fraction x in each position in the AlₓGa₍₁₋ₓ₎As layer 11. With the AlₓGa₍₁₋ₓ₎As layers 11 represented in FIGS. 9(A) through (C), the amount fraction x of Al in the rear faces 11b and in the major surfaces 11a are the same.

In FIGS. 9(A) through (C), imaginary triangles are formed by the highest position (Point A) along the diagonal y representing the amount fraction x of Al, when the point is extended downward, and the lowest position (Point B) along the diagonal y, when the point is extended leftward, and the extensions meet in a point of intersection (Point C). The total surface area of these triangles is the stress that is applied to the AlₓGa₍₁₋ₓ₎As layer 11. Warp occurs in the AlₓGa₍₁₋ₓ₎As layer 11 on account of this stress.

The present inventors discovered that warp in the AlₓGa₍₁₋ₓ₎As layer 11 is more likely to appear the greater is the separation z between the geometric center G of the triangles, and the center along the thickness of the AlₓGa₍₁₋ₓ₎As layer 11. The geometric center G is, in the instance illustrated in FIG. 9(A), the geometric center G of the triangle formed based on the diagonal y, while in the instances illustrated in FIGS. 9(B) and 9(C), it is the center along a line joining the geometric centers G1 through G3 of triangles formed based on the diagonals y. The geometric center G is where the resultant force of the stresses within the AlₓGa₍₁₋ₓ₎As layer 11 added together acts.

As indicated in FIGS. 9(A) through (C), the more the number of laminae in which the amount fraction x of Al monotonically decreases, the shorter becomes the separation z from the center along the thickness to the thickness point where the geometric center G is located, and thus the less warp occurs in the AlₓGa₍₁₋ₓ₎As layer 11. Therefore, forming a plurality of laminae in which the amount fraction x of Al monotonically decreases mitigates warp in a AlₓGa₍₁₋ₓ₎As substrate 10a. Herein, with the several triangles in the figures, the maximum and minimum values of the amount fraction x of Al, and the thickness of the AlₓGa₍₁₋ₓ₎As layer 11 are the same, but they do not necessarily have to be the same: They are adjustable depending on such factors as the transmissivity, warp, and state of the interfaces.

### Embodying Mode 2

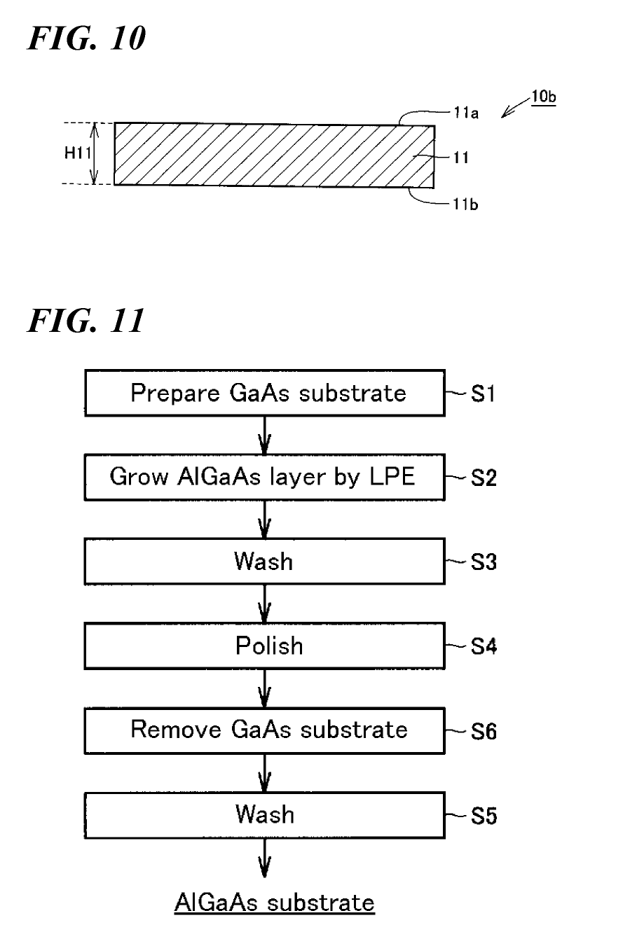

Referring to FIG. 10, an explanation of an AlₓGa₍₁₋ₓ₎As substrate 10b in the present embodying mode will be made.

As represented in FIG. 10, an AlₓGa₍₁₋ₓ₎As substrate 10b in the present embodying mode is basically furnished with the same structural makeup as an AlₓGa₍₁₋ₓ₎As substrate 10a of Embodying Mode 1, but differs in that it is not furnished with a GaAs substrate 13.

Specifically, the AlₓGa₍₁₋ₓ₎As substrate 10b is furnished with an AlₓGa₍₁₋ₓ₎As layer 11 having a major surface 11a and, on the reverse side from the major surface 11a, a rear face 11b. Then in the AlₓGa₍₁₋ₓ₎As layer 11, the amount fraction x of Al in the rear face 11b is greater than the amount fraction x of Al in the major surface 11a.

It is preferable that the thickness of an AlₓGa₍₁₋ₓ₎As layer 11 in the present embodying mode be thick enough for the AlₓGa₍₁₋ₓ₎As substrate 10b to be a freestanding substrate. Such thickness H11 is, for example, 70 μm or more.

To continue: With reference to FIG. 11, an explanation of a method of manufacturing an AlₓGa₍₁₋ₓ₎As substrate 10b in the present embodying mode will be made.

As indicated in FIG. 11, initially, in the same manner as in Embodying Mode 1, Step S1 of preparing a GaAs substrate 13, Step S2 of growing an AlₓGa₍₁₋ₓ₎As layer 11 by liquid-phase epitaxy, washing Step S3, and polishing Step S4 are implemented. An AlₓGa₍₁₋ₓ₎As substrate 10a as represented in FIG. 1 is thereby manufactured.

Next, the GaAs substrate 13 is removed (Step S6). For the removal method, a technique such as polishing or etching, for example, can be employed. “Polishing” refers to employing a polishing agent such as alumina, colloidal silica, or diamond in grinding equipment fitted with diamond grinding wheels, to mechanically abrade away the GaAs substrate 13. “Etching” refers to carrying out GaAs substrate 13 removal employing an etchant selected by optimally mixing, for example, ammonia, hydrogen peroxide, etc. to have a slow etching rate on AlₓGa₍₁₋ₓ₎As, but a fast etching rate on GaAs.

Next, washing Step S5 is implemented in the same manner as in Embodying Mode 1.

Implementing the foregoing Steps S1, S2, S3, S4, S6, and S5 makes it possible to manufacture an AlₓGa₍₁₋ₓ₎As substrate 10b as represented in FIG. 10.

It should be understood that apart from the foregoing, the AlₓGa₍₁₋ₓ₎As substrate 10b and its method of manufacture are otherwise of the same constitution as the AlₓGa₍₁₋ₓ₎As substrate 10a and its method of manufacture in Embodying Mode 1; thus identical components are labeled with identical reference marks, and their explanation will not be repeated.

As described in the foregoing, the AlₓGa₍₁₋ₓ₎As substrate 10b in the present embodying mode is an AlₓGa₍₁₋ₓ₎As substrate 10b furnished with an AlₓGa₍₁₋ₓ₎As layer 11 having a major surface 11a and, on the reverse side from the major surface 11a, a rear face 11b, and is characterized in that in the AlₓGa₍₁₋ₓ₎As layer 11, the amount fraction x of Al in the rear face 11b is greater than the amount fraction x of Al in the major surface 11a.

In addition, a method of manufacturing an AlₓGa₍₁₋ₓ₎As substrate 10b in the present embodying mode is provided with a step (Step S6) of removing the GaAs substrate 13.

According to an AlₓGa₍₁₋ₓ₎As substrate 10b and a method of manufacturing an AlₓGa₍₁₋ₓ₎As substrate 10b in the present embodying mode, an AlₓGa₍₁₋ₓ₎As substrate 10b furnished only with an AlₓGa₍₁₋ₓ₎As layer 11, but not furnished with a GaAs substrate 13, may be realized. Since the GaAs substrate 13 absorbs light of 900 nm or less wavelength, growing epitaxial layers onto an AlₓGa₍₁₋ₓ₎As substrate 10b from which the GaAs substrate 13 has been removed enables the manufacture of epitaxial wafers for infrared LEDs. Employing such infrared-LED epitaxial wafers to manufacture infrared LEDs enables the realization of infrared LEDs in which a high level of transparency is maintained, and which have superior device characteristics.

### Embodying Mode 3

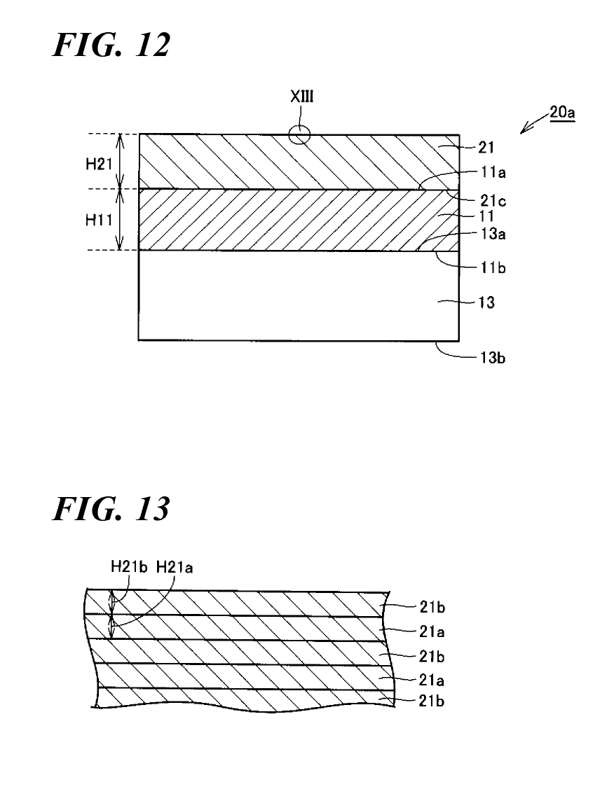

Referring to FIG. 12, an explanation of an epitaxial wafer 20a in the present embodying mode will be made.

As indicated in FIG. 12, the epitaxial wafer 20a is furnished with an AlₓGa₍₁₋ₓ₎As substrate 10a, represented in FIG. 1, of Embodying Mode 1, and, formed onto the major surface 11a of the AlₓGa₍₁₋ₓ₎As layer 11, an epitaxial layer containing an active layer 21. More specifically, the epitaxial wafer 20a is furnished with a GaAs substrate 13, an AlₓGa₍₁₋ₓ₎As layer 11 formed onto the GaAs substrate 13, and, formed onto the AlₓGa₍₁₋ₓ₎As layer 11, an epitaxial layer containing an active layer 21. The energy bandgap of the active layer 21 is smaller than that of the AlₓGa₍₁₋ₓ₎As layer 11.

It is preferable that the amount fraction x of Al in the plane of contact of the active layer 21 with the AlₓGa₍₁₋ₓ₎As layer 11 (in the active layer's rear face 21c) be greater than the amount fraction x of Al in the plane of contact of the AlₓGa₍₁₋ₓ₎As layer 11 with the active layer 21 (in the major surface 11a in the present embodying mode). It is also preferable that the amount fraction x of Al in the lamina of greatest thickness in the epitaxial layer containing the active layer 21 be greater than the amount fraction x of Al in the plane of contact of the AlₓGa₍₁₋ₓ₎As layer 11 with the active layer 21 (in the major surface 11a in the present embodying mode). Such an implementation makes it possible to mitigate warp that occurs in the epitaxial wafer 20a.

It should be understood that the region XIII depicted in FIG. 12 is not limited to an upper portion within the active layer 21. It is preferable that, as indicated in FIG. 13, the active layer 21 have a multiquantum-well structure. The active layer 21 contains two or more well layers 21a. The well layers 21a are each sandwiched between barrier layers 21b whose energy bandgap is larger than that of the well layers 21a. In particular, the plural well layers 21a are arranged alternating with plural barrier layers 21b whose bandgap is larger than that of the well layers 21a. With the active layer 21, all of the plurality of well layers 21a may be sandwiched between barrier layers 21b, or a well layer 21a may be arranged on at least one surface of the active layer 21, and the well layer 21a arranged on the one surface of the active layer 21 may be sandwiched between a barrier layer 21b and another layer (not illustrated), such as a guide layer or a cladding layer, disposed on the front side of the well layer 21a.

The active layer 21 preferably has between two and one-hundred (both inclusive), more preferably between ten and fifty (both inclusive), well layers 21a and barrier layers 21b, respectively. Implementations having two or more well layers 21a and barrier layers 21b constitute a multiquantum-well structure. Having ten or more well layers 21a and barrier layers 21b improves light output by improving the optical emission efficiency. Implementations with no more than one-hundred layers reduce the costs required in order to build the active layer 21, and implementations with no more than fifty layers further reduce such costs.

The thickness H21 of the active layer 21 preferably is between 6 nm and 2 μm (both inclusive). A thickness H21 of 6 nm or more allows the optical intensity to be improved. A thickness H21 of 2 μm or less allows productivity to be improved.

The thickness H21a of the well layers 21a preferably is between 3 nm and 20 nm (both inclusive). The thickness H21b of the barrier layers 21b preferably is between 5 nm and 1 μm (both inclusive).

While the material constituting the well layers 21a is not particularly limited as long as it has a bandgap that is smaller than that of the barrier layers 21b, materials such as GaAs, AlGaAs, InGaAs (indium gallium arsenide), and AlInGaAs (aluminum indium gallium arsenide) can be utilized. These materials are infrared light-emitting substances whose lattice match with AlGaAs is quite suitable.

In instances where the epitaxial wafer 20a is utilized in an infrared LED whose emission wavelength is 900 nm or greater, preferably the material for the well layers 21a is InGaAs that contains In, and in which the amount fraction of the In is 0.05 or greater. And in instances in which the well layers 21a include a material that contains In, the well layers 21a and the barrier layers 21b preferably are an active layer 21 having four or fewer laminae of each, more preferably an active layer 21 having three or fewer laminae of each.

While the material for the barrier layers 21b is not limited as long as the bandgap is larger than that of the well layers 21a, AlGaAs, InGaP, AlInGaP, InGaAsP and like materials may be utilized. These are materials whose lattice match with AlGaAs is suitable.

In instances where an epitaxial wafer 20a whose emission wavelength is 900 nm or greater, preferably 940 nm or greater, is utilized in an infrared LED, preferably the material for the barrier layers 21b within the active layer 21 contains P, or is either GaAsP or AlGaAsP in which the amount fraction of the P is 0.05 or more. Likewise, in instances in which the barrier layers 21b include a material that contains P, preferably the well layers 21a and the barrier layers 21b are an active layer 21 that has three or more laminae of each.

It is preferable that the concentration of atomic elements apart from the atoms within the epitaxial layer containing the active layer 21 (for example, elements such as atoms within the epitaxial growth ambient) be low.

It will be appreciated that the active layer 21, not particularly limited to being a multiquantum-well structure, may be composed of a single layer, or may be a double-heterostructure.

Furthermore, although in the present embodying mode an implementation in which only the active layer 21 is included as an epitaxial layer has been explained, other layers such as cladding layers and undoped layers may also be included.

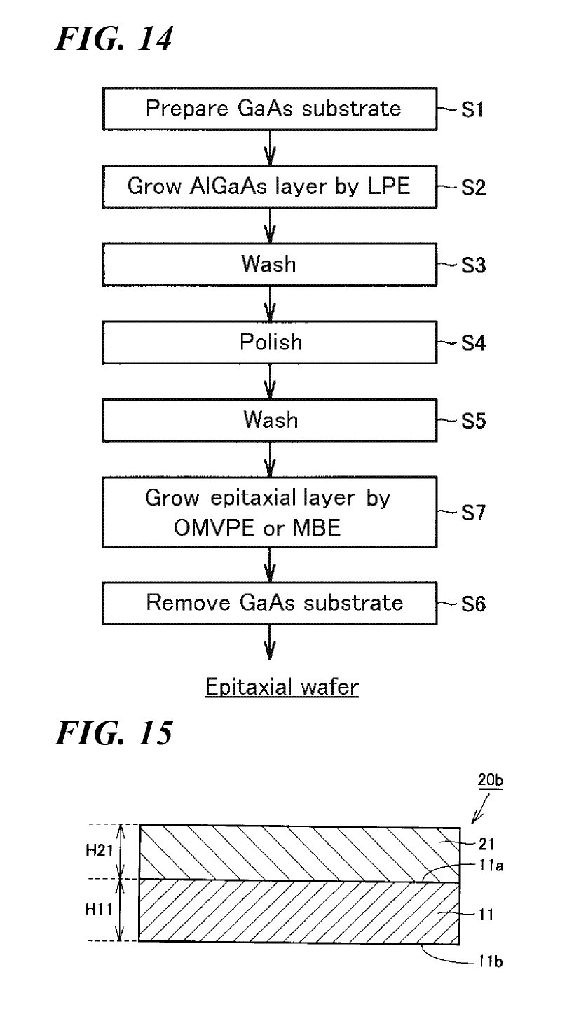

To continue: With reference to FIG. 14, an explanation of a method of manufacturing an infrared-LED epitaxial wafer 20a in the present embodying mode will be made.

As indicated in FIG. 14, initially an AlₓGa₍₁₋ₓ₎As substrate 10a is manufactured by a method in Embodying Mode 1 of manufacturing an AlₓGa₍₁₋ₓ₎As substrate 10a (Steps S1 through S5).

Next, an epitaxial layer containing an active layer 21 is deposited by organometallic vapor-phase epitaxy onto the major surface 11a of the AlₓGa₍₁₋ₓ₎As layer 11 (Step S7).

In Step S7, it is preferable that the epitaxial layer (the active layer 21 in the present embodying mode) be formed in such a manner that the amount fraction x of Al in the plane of contact of the epitaxial layer with the AlₓGa₍₁₋ₓ₎As layer 11 (in the epitaxial layer's rear face 21c) is greater than the amount fraction x of Al in the plane of contact of the AlₓGa₍₁₋ₓ₎As layer with the epitaxial layer (in the major surface 11a in the present embodying mode). It is also preferable that the amount fraction x of Al in the lamina of greatest thickness in the epitaxial layer be greater than the amount fraction x of Al in the plane of contact of the AlₓGa₍₁₋ₓ₎As layer 11 with the epitaxial layer.

Organometallic vapor-phase epitaxy grows an active layer 21 by precursor gases thermal-decomposition reacting above the AlₓGa₍₁₋ₓ₎As layer 11, and molecular-beam epitaxy grows an active layer 21 by a technique that does not mediate the chemical-reaction stages in a non-equilibrium system; thus, the OMVPE and MBE techniques allow the thickness of the active layer 21 to be readily controlled.

An active layer 21 having plural well layers 21a of two or more laminae may therefore be grown.

Furthermore, the thickness H21 of the epitaxial layer (active layer 21 in the present embodying mode) relative to the thickness H11 of the AlₓGa₍₁₋ₓ₎As layer 11 (the ratio H21/H11) is, for example, between 0.05 and 0.25 (both inclusive), more preferably between 0.15 and 0.25 (both inclusive). Such implementations make it possible to mitigate incidence of warp in the state in which an epitaxial layer has been grown onto an AlₓGa₍₁₋ₓ₎As layer 11.

In this Step S7, an epitaxial layer containing an active layer 21 as described above is grown onto the AlₓGa₍₁₋ₓ₎As layer 11.

Specifically, an active layer 21 is formed having between two and one-hundred (both inclusive), more preferably between ten and fifty (both inclusive), well layers 21a and barrier layers 21b, respectively.

It is also preferable that the active layer 21 be grown so as to have a thickness H21 of from 6 nm to 2 μm. Growing well layers 21a having a thickness H21a of from 3 nm to 20 nm, and barrier layers 21b having a thickness H21b of from 5 nm to 1 μm is likewise preferable.

Growing well layers 21a made from GaAs, AlGaAs, InGaAs, AlInGaAs, or the like, and barrier layers 21b made from AlGaAs, InGaP, AlInGaP, GaAsP, AlGaAsP, InGaAsP, or the like is also preferable.

For the active layer 21 it does not matter whether there is lattice misalignment (lattice relaxation) in the GaAs and AlGaAs that constitute the AlₓGa₍₁₋ₓ₎As substrate. If there is lattice misalignment in the well layers 21a, lattice misalignment in the opposite direction may be imparted to the barrier layers 21b, and for the structure of the epitaxial wafer overall, to balance the crystal warp from compression-extension. Further, the crystal warpage may be may be at or below or at or above the lattice-relaxing limit. If at or above the lattice-relaxing limit, however, because dislocations threading through the crystal are liable to occur, being at or below the limit is desirable.

As an example, an instance in which InGaAs is utilized for the well layer 21a will be given. Because the lattice constant of InGaAs is large with respect to the GaAs substrate, lattice relaxation occurs if an epitaxial layer of a fixed thickness or greater is grown. Therefore, favorable crystal in which the occurrence of crystal-threading dislocations is controlled to a minimum can be obtained by having the thickness be below the level at which lattice relaxation occurs.

Also, if GaAsP is utilized for the barrier layers 21b, because the lattice constant of GaAsP is small relative to the GaAs substrate, lattice relaxation occurs when epitaxial layer of fixed thickness or greater is grown thereon. Therefore, favorable crystal in which the occurrence of crystal-threading dislocations is controlled to a minimum can be obtained by having the thickness be below the level at which lattice relaxation occurs.

Lastly, with respect to the GaAs substrate, taking advantage of the features that the lattice constant of InGaAs is large while the lattice constant of GaAsP is small, by utilizing InGaAs for the well layers 21a and utilizing GaAsP for the barrier layers 21b to balance out the lattice warp in the crystal as a whole favorable crystal in which the occurrence of crystal-threading dislocations is controlled to a minimum can be obtained without causing lattice relaxation up to or above the aforementioned limit.

By implementing the foregoing Steps S1 through S5 and S7, the epitaxial wafer 20a depicted in FIG. 12 may be manufactured.

It will be appreciated that Step S6 of removing the GaAs substrate 13 may be additionally be implemented. Step S6 here may be implemented, for example, after Step S7 of growing an epitaxial layer, but is not particularly limited to that sequence. Step S6 may be implemented in between polishing Step S4 and washing Step S5, for example. Step S6 here is the as Step S6 of Embodying Mode 2 and thus its explanation will not be repeated. In instances in which Step S6 is implemented, a structure that is the same as that of later-described epitaxial wafer 20b of FIG. 15 results.

As described in the foregoing, an infrared-LED epitaxial wafer 20a in the present embodying mode is furnished with an AlₓGa₍₁₋ₓ₎As substrate 10a of Embodying Mode 1, and an epitaxial layer, formed on the major surface 11a of the AlₓGa₍₁₋ₓ₎As layer 11 and containing an active layer 21.

Furthermore, a method of manufacturing an infrared-LED epitaxial wafer 20a in the present embodying mode is provided with a procedure (Steps S1 through S6) of manufacturing an AlₓGa₍₁₋ₓ₎As substrate 10a by an AlₓGa₍₁₋ₓ₎As substrate 10a manufacturing method of Embodying Mode 1, and a step (Step S7) of forming an epitaxial layer containing an active layer 21 onto the major surface 11a of the AlₓGa₍₁₋ₓ₎As layer 11 by at least either organometallic vapor-phase epitaxy or molecular-beam epitaxy.

According to an infrared-LED epitaxial wafer 20a and a method of its manufacture in the present embodying mode, an epitaxial layer is formed onto an AlₓGa₍₁₋ₓ₎As substrate 10a furnished with an AlₓGa₍₁₋ₓ₎As layer 11 in which the amount fraction x of Al in the major surface 11a is lower than in the rear face 11b. Consequently, an infrared-LED epitaxial wafer 20a can be realized in which a high level of transparency is maintained, and with which, when the epitaxial wafer 20a is utilized to fabricate a device, the device proves to have superior characteristics.

In the above-described infrared-LED epitaxial wafer 20a and method of is manufacture, it is preferable that the amount fraction x of Al in the plane of contact of the epitaxial layer with the AlₓGa₍₁₋ₓ₎As layer 11 (the reverse face 21c of the epitaxial layer) be greater than the amount fraction x of Al in the plane of contact of the AlₓGa₍₁₋ₓ₎As layer 11 with the epitaxial layer (the major surface 11a).

These conditions, when the AlₓGa₍₁₋ₓ₎As layer 11 and the epitaxial layer are seen as a whole, can mitigate warp in the epitaxial wafer 20a, for the same reasons discussed in Embodying Mode 1.

In the above-described method of manufacturing an infrared-LED epitaxial wafer 20a, preferably provided are: a step of preparing a GaAs substrate 13 (Step S1); a step of growing onto the GaAs substrate 13 by liquid-phase epitaxy an AlₓGa₍₁₋ₓ₎As layer 11 as a window layer that diffuses current and that transmits light from the active layer (Step S2); a step of polishing the major surface 11a of the AlₓGa₍₁₋ₓ₎As layer 11 (Step S4); and a step growing onto the major surface 11a of the AlₓGa₍₁₋ₓ₎As layer 11 by at least either organometallic vapor-phase epitaxy or molecular-beam epitaxy an active layer 21 having a multiquantum-well structure and whose energy bandgap is smaller than that of the AlₓGa₍₁₋ₓ₎As layer 11 (Step S7).

Owing to the AlₓGa₍₁₋ₓ₎As layer 11 being grown (Step S2) by the LPE technique, the growth rate is rapid. With LPE, moreover, since expensive precursor gases and expensive apparatus need not be employed, the manufacturing costs are low. Therefore, more than with the OMVPE and MBE techniques, costs can be reduced and considerably thick AlₓGa₍₁₋ₓ₎As layers 11 formed. Unevenness on the major surface 11a of the AlₓGa₍₁₋ₓ₎As layer 11 can be reduced by polishing the major surface 11a of the AlₓGa₍₁₋ₓ₎As layer 11. Therefore, in forming an epitaxial layer containing an active layer 21 onto the major surface 11a of the AlₓGa₍₁₋ₓ₎As layer 11, abnormal growth of the epitaxial layer containing the active layer 21 can be kept under control. Meanwhile, OMVPE, by the thermal-decomposition reaction of the precursor gases, and MBE, which does not mediate the chemical-reaction stages in a non-equilibrium system, allow the film thickness to be optimally controlled. Consequently, forming the epitaxial layer containing the active layer 21 by OMVPE or MBE after Step S4 of polishing the major surface 11a enables abnormal growth to be held in check, and makes it possible to form an active layer having a multiquantum-well structure (MQW structure) in which the film thickness of the active layer 21 has been optimally controlled.

Especially since with LEDs, cases where the film thickness is less than with laser diodes (LDs) are numerous, utilizing the OMVPE or MBE technique, whereby film-thickness controllability is excellent, allows an epitaxial layer containing an active layer 21 having a multiquantum-well structure to be formed.

Here the active layer 21 is grown by OMVPE or MBE following Step S2 of growing the AlₓGa₍₁₋ₓ₎As layer 11 by LPE. Growing the active layer 21 by OMVPE or MBE following the liquid-phase epitaxy prevents extended-duration, high-temperature heat from being applied to the active layer 21. Deterioration of crystallinity due to crystalline defects arising in the active layer 21 on account of the high-temperature heat can therefore be prevented, and diffusion into the active layer 21 of dopant introduced by the LPE can held in check.

After Step S7 of growing the active layer 21 in the present embodying mode, the active layer 21 is not exposed to the high-temperature ambients employed in liquid-phase epitaxy. Thus p-type dopants for example, which diffuse readily, introduced into the AlₓGa₍₁₋ₓ₎As layer 11 can be prevented from diffusing to inside the active layer 21. Therefore, the concentration in the active layer 21 of p-type carriers such as Zn, Mg and C can be held low—to, for example, 1×10¹⁸ cm⁻³ or less. A further resulting advantage is that the formation of impurity bands in the active layer 21 can be prevented, allowing the difference in bandgap between the well layers 21a and the barrier layers 21b to be sustained.

Accordingly, since an active layer 21 having an improved-performance multiquantum-well structure can be formed, when the GaAs substrate 13 is removed (Step S6) and the device electrodes are formed, by the altering of the state density in the active layer 21 efficient recombination of electrons and holes takes place. Epitaxial wafers 20a for constituting infrared LEDs in which optical emission efficiency is improved can therefore be grown.

It will be appreciated that with the AlₓGa₍₁₋ₓ₎As layer 11 as a window layer, since electric current is diffused in a direction (horizontally in FIG. 1) that intersects the direction along which the AlₓGa₍₁₋ₓ₎As layer 11 and the active layer 21 are laminated (vertically in FIG. 1), the light-extraction efficiency is improved, thereby allowing the optical emission efficiency to be improved.

In the above-described method of manufacturing an infrared-LED epitaxial wafer 20a, it is preferable that Steps S3 and S5 of washing the surface of the AlₓGa₍₁₋ₓ₎As layer 11 be provided at least either between AlₓGa₍₁₋ₓ₎As layer 11 growth Step S2 and polishing Step S4, or between polishing Step S4 and epitaxial layer growth Step S7.

Even should impurities cling to or mix into the AlₓGa₍₁₋ₓ₎As layer 11 due to the AlₓGa₍₁₋ₓ₎As layer 11 coming into contact with atmospheric air, thus providing the washing steps clears the impurities away.

In the above-described method of manufacturing an infrared-LED epitaxial wafer 20a, it is preferable that in washing Steps S3 and A5, an alkaline solution be employed to wash the major surface 11a.

When impurities have clung to or mixed into the AlₓGa₍₁₋ₓ₎As layer 11, this preferred application of the washing steps allows the impurities to be more effectively removed from the AlₓGa₍₁₋ₓ₎As layer 11.

In the above-described infrared-LED epitaxial wafer 20a and method of its manufacture, it is preferable that the thickness H11 of the AlₓGa₍₁₋ₓ₎As layer 11 be between 10 μm and 1000 μm (both inclusive), and more preferable that it be between 20 μm and 140 μm (both inclusive).

Implementations in which the thickness H11 is as least 10 μm allow optical emission efficiency to be improved, while implementations in which the thickness H11 is 20 μm or more enable further improvement of emission efficiency. Keeping the thickness H11 to 1000 μm or less reduces the costs required to form the AlₓGa₍₁₋ₓ₎As layer 11, while keeping the thickness H11 to 140 μm or less further allows the costs involved in the deposition of the AlₓGa₍₁₋ₓ₎As layer 11 to be held down.

In the above-described infrared-LED epitaxial wafer 20a and method of its manufacture, it is preferable that in the active layer 21, the well layers 21a be disposed in alternation with the barrier layers 21b of bandgap larger than that of the well layers 21a, and that the active layer 21 has between ten and fifty (both inclusive) well layers 21a and between ten and fifty (both inclusive) barrier layers 21b.

Implementations with ten or more layers allow further improvement in emission efficiency, while implementations with no more than fifty layers allow the costs involved in forming the active layer 21 to be held down.

With the above-described epitaxial wafer 20a for infrared LEDs and the method of its manufacture, preferably the epitaxial wafer, and its method of manufacture, are utilized in an infrared LED whose emission wavelength is 900 nm or greater, and the well layers 21a within the active layer 21 include a material containing In, with the number of well layers 21a being four or fewer laminae. That the emission wavelength be 940 nm or greater is more preferable.

By forming an active layer 21 including a material containing In and having well layers of four or fewer laminae, the present inventors discovered that lattice relaxation was controlled to a minimum. They therefore were able to realize an epitaxial wafer that can be utilized in an infrared LED whose wavelength is 900 nm or greater.

In the foregoing infrared-LED epitaxial wafer 20a and method of its manufacture, preferably the well layers 21a are of InGaAs in which the amount fraction of indium is 0.05 or greater.

That makes it possible to realize a useful epitaxial wafer 20a that can be utilized in an infrared LED whose wavelength is 900 nm or greater.

With the above-described epitaxial wafer 20a for infrared LEDs and the method of its manufacture, preferably the epitaxial wafer, and its method of manufacture, are utilized in an infrared LED whose emission wavelength is 900 nm or greater, and the barrier layers 21b within the active layer 21 include a material containing P, with the number of barrier layers 21b being three or more laminae.

By forming an active layer 21 including a material containing P, the present inventors discovered that lattice relaxation was controlled to a minimum. They therefore were able to realize an epitaxial wafer that can be utilized in an infrared LED whose wavelength is 900 nm or greater.

In the foregoing infrared-LED epitaxial wafer and method of its manufacture, preferably the barrier layers 21b are of either GaAsP or AlGaAsP in which the amount fraction of P is 0.05 or greater.

That makes it possible to realize a useful epitaxial wafer 20a that can be utilized in an infrared LED whose wavelength is 900 nm or greater.

### Embodying Mode 4

Referring to FIG. 15, an explanation of an infrared-LED epitaxial wafer 20b in the present embodying mode will be made.

As indicated in FIG. 15, an epitaxial wafer 20b in the present embodying mode is furnished with an AlₓGa₍₁₋ₓ₎As substrate 10b, represented in FIG. 10, of Embodying Mode 2, and, formed onto the major surface 11a of the AlₓGa₍₁₋ₓ₎As layer 11, an epitaxial layer containing an active layer 21.

An epitaxial wafer 20b in the present embodying mode is furnished with basically the same structural makeup as an epitaxial wafer 20a of Embodying Mode 3, but differs in that it is not furnished with a GaAs substrate 13.

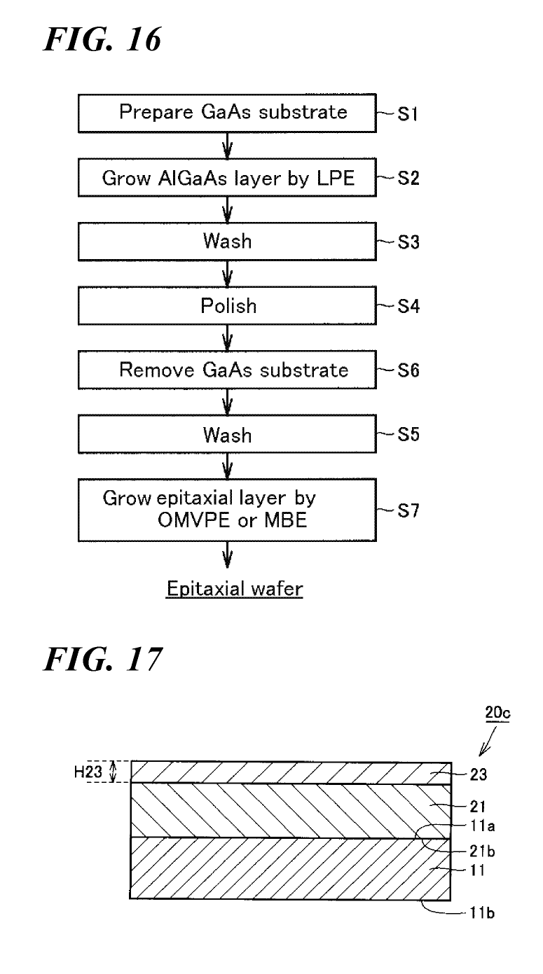

To continue: With reference to FIG. 16, an explanation of a method of manufacturing an epitaxial wafer 20b in the present embodying mode will be made.

As indicated in FIG. 16, initially an AlₓGa₍₁₋ₓ₎As substrate 10b is manufactured by a method in Embodying Mode 2 of manufacturing an AlₓGa₍₁₋ₓ₎As substrate 10b (Steps S1, S2, S3, S4, S6 and S5).

Next, in the same manner as in Embodying Mode 3, an epitaxial layer containing an active layer 21 is deposited by organometallic vapor-phase epitaxy onto the major surface 11a of the AlₓGa₍₁₋ₓ₎As layer 11 (Step S7).

Implementing the foregoing Steps S1 through S7 enables an infrared-LED epitaxial wafer 20b, represented in FIG. 15, to be manufactured.

It should be understood that apart from the foregoing, the infrared-LED epitaxial wafer and its method of manufacture are otherwise of the same constitution as the infrared-LED epitaxial wafer 20a and its method of manufacture in Embodying Mode 3; thus identical components are labeled with identical reference marks, and their explanation will not be repeated.

As described in the foregoing, the infrared-LED epitaxial wafer 20b in the present embodying mode is furnished with an AlₓGa₍₁₋ₓ₎As layer 11, and an epitaxial layer formed on the major surface 11a of the AlₓGa₍₁₋ₓ₎As layer 11 and containing an active layer 21.

In addition, a method of manufacturing an infrared-LED epitaxial wafer 20b in the present embodying mode is provided with a step (Step S6) of removing the GaAs substrate 13.

According to an infrared-LED epitaxial wafer 20b and its method of manufacture in the present embodying mode, an AlₓGa₍₁₋ₓ₎As substrate 10b from which the GaAs substrate, which absorbs light in the visible range, has been removed is utilized. Consequently, further forming electrodes on the epitaxial wafer 20b enables the realization of an infrared-LED-constituting epitaxial wafer 20b in which a high level of transparency is maintained and superior device characteristics are sustained.

### Embodying Mode 5

Referring to FIG. 17, an explanation of an infrared-LED epitaxial wafer 20c in the present embodying mode will be made.

As indicated in FIG. 17, an epitaxial wafer 20c in the present embodying mode is furnished with a structural makeup that is basically the same as that of an epitaxial wafer 20b of Embodying Mode 4, but differs in that the epitaxial layer further includes a contact layer 23. That is, in the present embodying mode, the epitaxial layer contains an active layer 21 and a contact layer 23.

Specifically, the epitaxial wafer 20c is furnished with an AlₓGa₍₁₋ₓ₎As layer 11, an active layer 21 formed on the AlₓGa₍₁₋ₓ₎As layer 11, and a contact layer 23 formed on the active layer 21.

The contact layer 23 consists of, for example, p-type GaAs and has a thickness H23 of 0.01 μm or more.

To continue: A method of manufacturing an infrared-LED epitaxial wafer 20c in the present embodying mode will be made. The method of manufacturing an infrared-LED epitaxial wafer 20c in the present embodying mode is furnished with the same constitution as the epitaxial wafer 20b manufacturing method of Embodying Mode 4, but differs in that Step S7 of forming an epitaxial layer further includes a substep of forming a contact layer 23.

Specifically, after the active layer 21 is grown, a contact layer 23 is formed onto the surface of the active layer 21. Although the method whereby the contact layer 23 is formed is not particularly limited, preferably it is grown by at least either organometallic vapor-phase epitaxy or molecular-beam-epitaxy, or else by a combination of OMVPE and MBE, because these deposition techniques enable the formation of thin-film layers. And the contact layer 23 is preferably grown by the same technique as is the active layer 21, because it can then be grown continuously with growth of the active layer 21.

It should be understood that apart from the foregoing, the infrared-LED epitaxial wafer and its method of manufacture are otherwise of the same constitution as the infrared-LED epitaxial wafer 20b and its method of manufacture in Embodying Mode 4; thus identical components are labeled with identical reference marks, and their explanation will not be repeated.

It will be appreciated that the infrared-LED epitaxial wafer 20c and its method of manufacture in the present embodying mode can find application not only in Embodying Mode 4, but in Embodying Mode 3 as well.

### Embodying Mode 6

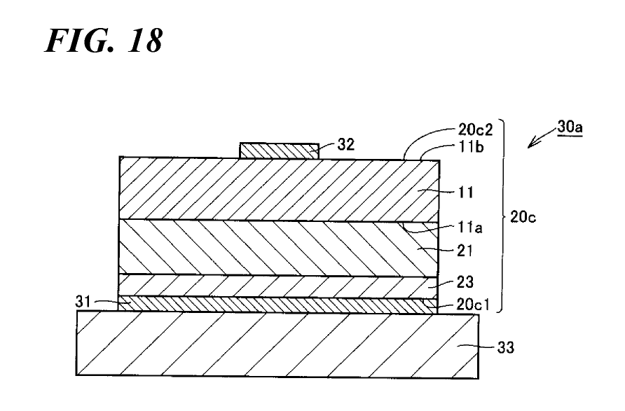

Referring to FIG. 18, an explanation of an infrared LED 30a in the present embodying mode will be made. As indicated in FIG. 18, an infrared LED 30a in the present embodying mode is furnished with an infrared-LED epitaxial wafer 20c, represented in FIG. 17, of Embodying Mode 5, electrodes 31 and 32, formed respectively on the front side 20c1 and back side 20c2 of the epitaxial wafer 20c, and a stem 33.

The electrode 31 is provided contacting on the front side 20c1 of the epitaxial wafer 20c (on the contact layer 23 in the present embodying mode), while the electrode 32 is provided contacting on the back side 20c2 (on the AlₓGa₍₁₋ₓ₎As layer 11 in the present embodying mode). The stem 33 is provided contacting on the electrode 31, on its reverse side from the epitaxial wafer 20c.

To give specifics of the LED 30a makeup: The stem 33 is constituted from, for example, an iron-based material. The electrode 31 is a p-type electrode constituted from, for example, an alloy of gold (Au) and zinc (Zn). The electrode 31 is formed onto the p-type contact layer 23. The contact layer 23 is formed on the top of the active layer 21. The active layer 21 is formed on the top of the AlₓGa₍₁₋ₓ₎As layer 11. The electrode 32 formed onto the AlₓGa₍₁₋ₓ₎As layer 11 is an n-type electrode constituted from, for example, an alloy of Au and Ge (germanium).

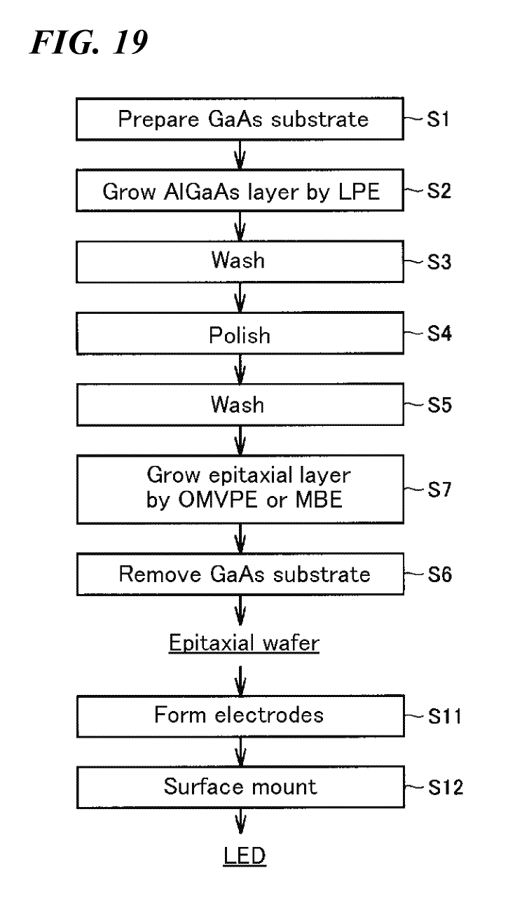

To continue: With reference to FIG. 19, an explanation of a method of manufacturing an infrared LED 30a in the present embodying mode will be made.

Initially, an epitaxial wafer 20a is manufactured by the procedure of Embodying Mode 3 for manufacturing an infrared-LED epitaxial wafer 20a (Step S1 through S5, and S7). In this case, the active layer 21 and the contact layer 23 are formed in epitaxial layer growth Step S7. Next, the GaAs substrate is removed (Step S6). It will be appreciated that implementing Step S6 allows an infrared-LED epitaxial wafer 20c as represented in FIG. 17 to be manufactured.

Subsequently, electrodes 31 and 32 are formed on the front side 20c1 and back side 20c2 of the infrared-LED epitaxial wafer 20c (Step S11). Specifically, for example, by a vapor-deposition technique, Au and Zn are vapor-deposited onto the front side 20c1, and further, Au and Ge are alloyed after being vapor-deposited onto the back side 20c2, to form the electrodes 31 and 32.

Next, the LED is surface mounted (Step S12). Specifically, for example the electrode 31 side is turned down, and die attachment is carried out on the stem 33 with a die-attach adhesive such as an Ag paste, or with an eutectic alloy such as AuSn.

Implementing the foregoing Steps S1 through S12 enables an infrared-LED 30a, represented in FIG. 18, to be manufactured.

It should be understood that in the present embodying mode, although an implementation utilizing an infrared-LED epitaxial wafer 20c of Embodying Mode 5 has been described, an infrared-LED epitaxial wafer 20a or 20b of Embodying Mode 3 or 4 is also applicable. Prior to completion of the infrared LED 30a, however, it is advisable to implement Step S6 of removing the GaAs substrate 13. Still, in implementations where the GaAs substrate 13 is not removed, an electrode may be formed on the rear face of the GaAs substrate 13.

As described in the foregoing, an infrared LED 30a in the present embodying mode is furnished with: an AlₓGa₍₁₋ₓ₎As substrate 10b of Embodying Mode 2; an epitaxial layer formed onto the major surface 11a of the AlₓGa₍₁₋ₓ₎As layer 11 and containing an active layer 21; a first electrode 31, formed on the front side 20c1 of the epitaxial layer; and a second electrode 32, formed on the back side 20c2 of the AlₓGa₍₁₋ₓ₎As layer 11.

In turn, a method of manufacturing an infrared LED 30a in the present embodying mode is furnished with: a procedure of manufacturing an AlₓGa₍₁₋ₓ₎As substrate 10b by an AlₓGa₍₁₋ₓ₎As substrate 10b manufacturing method of Embodying Mode 2 (Steps S1 through S6); a step of forming an epitaxial layer containing an active layer 21 onto the major surface 11a of the AlₓGa₍₁₋ₓ₎As layer 11 by organometallic vapor-phase epitaxy (Step S7); a step of forming a first electrode 31 onto the front side 20c1 of the epitaxial wafer 20c (Step S11); and a step of forming a second electrode 32 onto the rear face 11b of the AlₓGa₍₁₋ₓ₎As layer 11 (Step S11).

According to an infrared LED 30a and method of its manufacture in the present embodying mode, since an AlₓGa₍₁₋ₓ₎As substrate 10b in which the amount fraction x of Al in the AlₓGa₍₁₋ₓ₎As layer 11 has been controlled is employed, infrared LEDs 30a that sustain a high level of transmissivity, and which, in the fabrication of semiconductor devices, have superior characteristics may be realized.

Furthermore, the electrode 31 is formed on the wafer's active layer 21 side, while the electrode 32 is formed on its AlₓGa₍₁₋ₓ₎As layer 11 side. This structure enables current from the electrode 32 to be diffused across the entire surface of the infrared LED 30a by means of the AlₓGa₍₁₋ₓ₎As layer 11. Infrared LEDs 30a of further improved optical emission efficiency can therefore be obtained.

### Embodying Mode 7

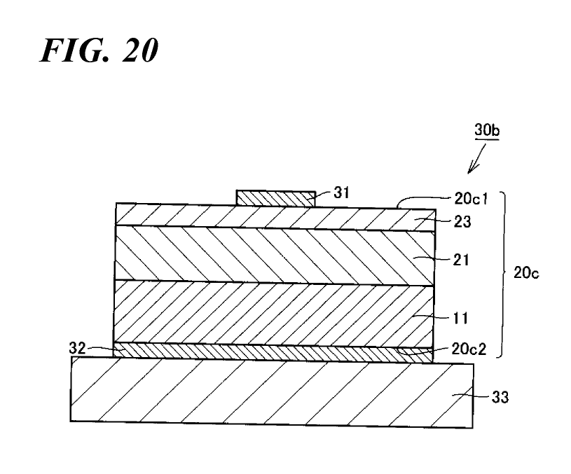

Referring to FIG. 20, an explanation of an infrared LED 30b in the present embodying mode will be made. As indicated in FIG. 20, an infrared LED 30b in the present embodying mode is furnished with basically the same structural makeup as an infrared LED 30a of Embodying Mode 6, but differs in that the stem 33 is disposed on the wafer's AlₓGa₍₁₋ₓ₎As layer 11 side.

Specifically, the electrode 31 is provided contacting on the front side 20c1 of the epitaxial wafer 20c (on the contact layer 23 in the present embodying mode), while the electrode 32 is provided contacting on the back side 20c2 (on the AlₓGa₍₁₋ₓ₎As layer 11 in the present embodying mode).

To serve the purpose of extracting light, the electrode 31 covers a portion of the front side 20c1 of the epitaxial wafer 20c, leaving the remaining area on the front side 20c1 of the epitaxial wafer 20c exposed. The electrode 32, meanwhile, covers the entire surface of the back side 20c2 of the epitaxial wafer 20c.

A method of manufacturing an infrared LED 30b in the present embodying mode is furnished with the basically same constitution as the infrared LED 30a manufacturing method of Embodying Mode 6, but as just described differs in Step S11 of forming the electrodes 31 and 32.

It should be understood that apart from the foregoing, the infrared LED 30b and its method of manufacture are otherwise of the same constitution as the infrared LED 30a and its method of manufacture in Embodying Mode 6; thus identical components are labeled with identical reference marks, and their explanation will not be repeated.

Further, in instances in which the GaAs substrate 13 has not been removed, an electrode may be formed on the reverse face 13b of the GaAs substrate 13. With an epitaxial wafer 20a of Embodying Mode 3, in the case where an epitaxial wafer in which the epitaxial layer further contains contact layers is utilized to form an infrared LED, it will have a structure like infrared LED 30c illustrated in FIG. 27 as a representative example. In this case, as indicated in FIG. 27, the stem 33 is arranged on the GaAs substrate 13 side of the device. As a modified example of this, the GaAs substrate 13 side may be located on the opposite side from that of the stem 33.

### Embodiment 1

In the present embodiment, the effect of, in an AlₓGa₍₁₋ₓ₎As layer 11, the amount fraction x of Al in the rear face 11b being greater than the amount fraction x of Al in the major surface 11a was investigated. Specifically, an AlₓGa₍₁₋ₓ₎As substrate 10a was manufactured in conformance with the AlₓGa₍₁₋ₓ₎As substrate 10a manufacturing method of Embodying Mode 1.

More particularly, GaAs substrates 13 were prepared (Step S1). Next, a variety of AlₓGa₍₁₋ₓ₎As layers 11 whose amount fraction x of Al was 0≦x≦1 were grown on the GaAs substrates 13 by liquid-phase epitaxy (Step S2).

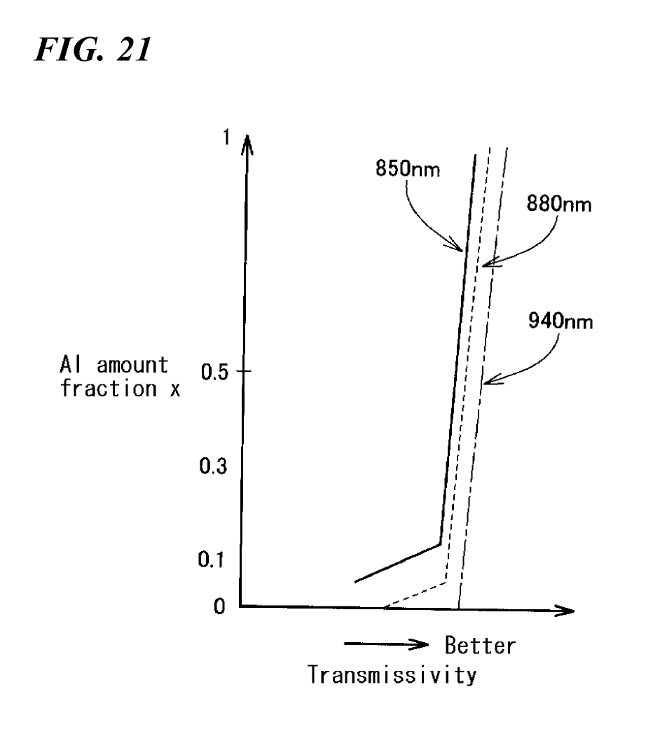

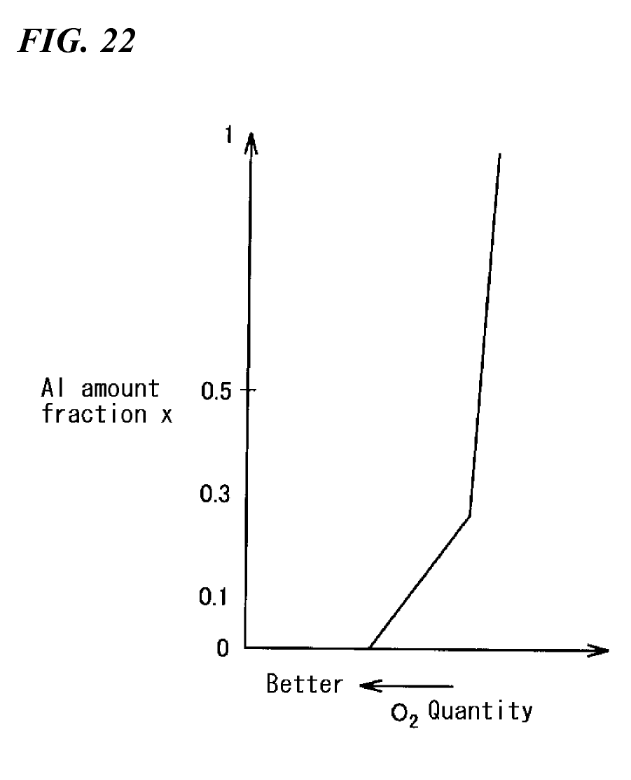

The transmissivity and surface oxygen quantity of AlₓGa₍₁₋ₓ₎As layers 11 when their emission wavelength was 850 nm, 880 nm and 940 nm were examined. In order to check these characteristics: the AlₓGa₍₁₋ₓ₎As layer 11 of FIG. 1 was created at thicknesses of 80 μm to 100 μm, in such a way that the amount fraction of Al depth-wise would be uniform; the GaAs substrate 13 was removed as in the flow of FIG. 11; and with the layers in the FIG. 10 state, their transmissivity was measured with a transmittance meter. For the oxygen quantity: the same samples were created, following the flow in FIG. 14; an epitaxial layer was grown by an OMVPE technique; and, before the GaAs substrate 13 was removed, the major surface 11a of the AlₓGa₍₁₋ₓ₎As layer 11 was measured by secondary ion mass spectrometry (SIMS) characterization. The results are presented in FIG. 21 and FIG. 22.

In FIG. 21, the vertical axis indicates amount fraction x of Al in the AlₓGa₍₁₋ₓ₎As layers 11, while the horizontal axis indicates transmissivity. The further to the right is the position along the axis in FIG. 21, the better is the transmissivity. Also, from looking at the case where the emission wavelength was 880 nm, it was understood that the transmissivity is favorable even with lower Al component levels. Also, in the case where the emission wavelength was 940 nm, it could be confirmed that even with lower Al component levels, deterioration in transmissivity was unlikely to occur.

Next, in FIG. 22, the vertical axis indicates amount fraction x of Al in the AlₓGa₍₁₋ₓ₎As layers 11, while the horizontal axis indicates surface oxygen quantity. The further to the left is the position along the axis in FIG. 22, the better is the oxygen quantity. It will be appreciated that the surface oxygen quantity was the same when the emission wavelength was 850 nm, 880 nm and 940 nm.

Herein, in the present embodiment, as described above the AlₓGa₍₁₋ₓ₎As layer 11 was created in such a way that the Al amount fraction depth-wise would be uniform, yet it was confirmed by the same experiment described earlier that because the oxygen quantity is determined principally by the amount fraction of Al in the major surface 11a of the AlₓGa₍₁₋ₓ₎As layer 11, even in instances in which the layer possesses a gradient in Al amount fraction, as illustrated in FIG. 2 through FIG. 5, the correlation with the Al amount fraction in the major surface is strong.

The same tendency holds true with respect to the transmissivity: In instances in which the layer possesses an Al amount fraction gradient as illustrated in FIG. 2 through FIG. 5, the transmissivity is affected by the area where the Al amount fraction is lowest. Specifically, in instances where the layer possesses a gradient as illustrated in FIG. 2 through FIG. 5, if the pattern of the gradient (layer number, gradient in each layer, thickness) and the gradient (ΔAl/distance) are the same, the correlation of the transmissivity to the size of the average Al amount fraction within the layer is strong.

It was recognized that, as shown in FIG. 21, the greater the amount fraction x of Al in the AlₓGa₍₁₋ₓ₎As layer 11 is, the more the transmissivity improves. Likewise, it was recognized that, as shown in FIG. 22, the lower the amount fraction x of Al in the AlₓGa₍₁₋ₓ₎As layer 11 is, the more the oxygen quantity contained in the major surface can be reduced.

From the foregoing, it was understood that according to the present embodiment, in the AlₓGa₍₁₋ₓ₎As layers 11, raising the amount fraction x of Al in the rear face 11b maintains a high level of transmissivity, while lowering the amount fraction x of Al in the major surface 11a enables the oxygen quantity in the major surface to be reduced.

### Embodiment 2

In the present embodiment, the effect of an AlₓGa₍₁₋ₓ₎As layer 11 furnishing a plurality of layers in each of which the amount fraction x of Al heading from the plane of the layer's rear face 11b side to the plane of its major surface 11a side monotonically decreases was investigated. Specifically, thirty-two different samples of AlₓGa₍₁₋ₓ₎As substrate 10a were manufactured in conformance with the FIG. 1 depicted AlₓGa₍₁₋ₓ₎As substrate 10a in the manufacturing method of Embodying Mode 1.

More particularly, 2-inch and 3-inch GaAs substrates were prepared (Step S1).

Next, AlₓGa₍₁₋ₓ₎As layers 11 were grown by a slow-cooling technique (Step S2). In Step S2, the layers were grown so as to contain one or more laminae in each of which, as diagrammed in FIG. 2, the amount fraction x of Al constantly decreased heading in the growth direction. In detail, thirty-two different samples of AlₓGa₍₁₋ₓ₎As layer 11 were grown in which the following parameters were as entered in Table I below: the Al amount fraction x in the major surface 11a of the AlₓGa₍₁₋ₓ₎As layer 11 (minimum value of Al amount fraction x); in each lamina, the difference between the Al amount fraction x in the plane of the layer's rear face 11b side and the Al amount fraction x in the plane of its major surface 11a side (difference in Al amount fraction x); and number of laminae in each of which the amount fraction x of Al heading from the plane of the layer's rear face 11b side to the plane of its major surface 11a side monotonically decreased (laminae number). Thirty-two different samples of AlₓGa₍₁₋ₓ₎As substrate 10a were thereby manufactured.

With regard to the AlₓGa₍₁₋ₓ₎As substrates 10a themselves, warp appearing in an AlₓGa₍₁₋ₓ₎As substrate 10a—the gap between the AlₓGa₍₁₋ₓ₎As substrate 10a with its convexly deviating surface face up, and a planar block—was measured by employing a thickness gauge. The results are tabulated in Table I below. In Table I, instances in which warp occurring in an AlₓGa₍₁₋ₓ₎As substrate 10a was 200 μm or less when a 2-inch GaAs substrate was used, and was 300 μm or less when a 3-inch GaAs substrate was used are designated “o,” while instances in which warp exceeded 200 μm when a 2-inch GaAs substrate was used, and exceeded 300 μm when a 3-inch GaAs substrate was used are designated “x.”

TABLE I

| Al amount | Al amount | Warp for each number of laminae | | | |
|---|---|---|---|---|---|
| fraction x | fraction x | | | 3 | 4 |
| min. value | difference | 1 lamina | 2 laminae | laminae | laminae |
| 0.1 to 0.3 | 0 ≦ x < 0.15 | ◯ | ◯ | ◯ | ◯ |
| | 0.15 ≦ x < 0.25 | X | ◯ | ◯ | ◯ |
| | 0.25 ≦ x < 0.35 | X | X | ◯ | ◯ |
| | 0.35 ≦ x | X | X | X | X |
| 0.3 to 0.5 | 0 ≦ x < 0.15 | ◯ | ◯ | ◯ | ◯ |
| | 0.15 ≦ x < 0.25 | X | ◯ | ◯ | ◯ |
| | 0.25 ≦ x < 0.35 | X | X | ◯ | ◯ |
| | 0.35 ≦ x | X | X | X | X |

As is evident from Table I, regardless of the Al amount fraction x in the major surface 11a, the smaller the difference in Al amount fraction x within the laminae in which the amount fraction x of Al monotonically decreases, the less likely warp was to occur in the AlₓGa₍₁₋ₓ₎As substrates 10a. It was understood that in instances in which the difference in Al amount fraction x was 0.15 or greater, but less than 0.35, warp could be mitigated by the AlₓGa₍₁₋ₓ₎As layer 11 including many of the laminae in which the amount fraction x of Al monotonically decreases. From this result, it was inferred that in instances in which the difference in Al amount fraction x was a small 0.15 or less, increasing the number of laminae in which the amount fraction x of Al monotonically decreases was efficacious if warp was to be further reduced. It was likewise inferred that in instances in which the difference in Al amount fraction x was 0.35 or greater, increasing the number of laminae in which the amount fraction x of Al monotonically decreases to five or more allowed warp to be mitigated. It should be noted that there were no special differences between using 2-inch and 3-inch GaAs substrates.

As described in the foregoing, it was confirmed that according to the present embodiment, warp in the AlₓGa₍₁₋ₓ₎As substrates 10a can be mitigated by the AlₓGa₍₁₋ₓ₎As layer 11 including a plurality of laminae in each of which the amount fraction x of Al heading from the plane of the layer's rear face 11b side to the plane of its major surface 11a side monotonically decreases.

### Embodiment 3

In the present embodiment, the effect of an infrared-LED epitaxial wafer providing an active layer with a multiquantum-well structure, and a satisfactory laminae number for the barrier layers and the well layers was investigated.

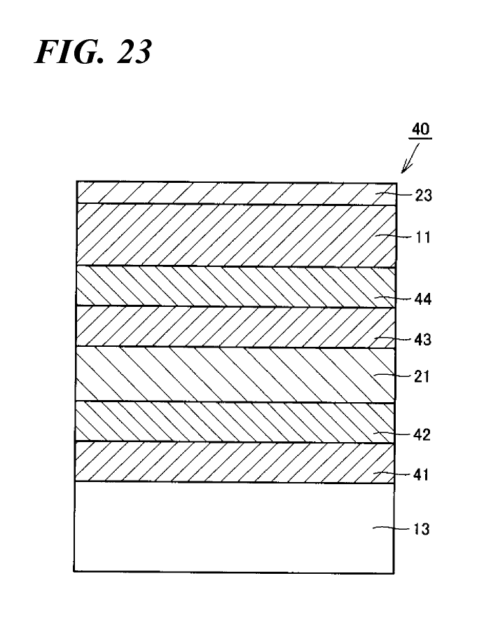

In the present embodiment, four different samples, indicated in FIG. 23, of epitaxial wafers 40 were grown in which only the thickness of, and number of laminae in, the active layer 21 having a multiquantum-well structure were varied.

Specifically, GaAs substrates 13 were prepared (Step S1). Next, by organometallic vapor-phase epitaxy, an n-type cladding layer 41, an undoped guide layer 42, an active layer 21, an undoped guide layer 43, a p-type cladding layer 44, an AlₓGa₍₁₋ₓ₎As layer 11, and a contact layer 23 were grown, in that order. The growth temperature for each layer was 750° C. The n-type cladding layers 41 had a thickness of 0.5 μm and consisted of Al_{0.35}Ga_{0.65}As; the undoped guide layers 42 had a thickness of 0.02 μm and consisted of Al_{0.30}Ga_{0.70}As; the undoped guide layers 43 had a thickness of 0.02 μm and consisted of Al_{0.30}Ga_{0.70}As; the p-type cladding layers 44 had a thickness of 0.5 μm and consisted of Al_{0.35}Ga_{0.65}As; the AlₓGa₍₁₋ₓ₎As layers 11 had a thickness of 2 μm and consisted of p-type Al_{0.15}Ga_{0.85}As; and the contact layers 23 had a thickness of 0.01 μm and consisted of p-type GaAs. Furthermore, the active layers 21 had a multiplequantum well structure (MQW) in which, respectively, the well layers and the barrier layers had two laminae, ten laminae, twenty laminae and fifty laminae, with the optical emission wavelength being from 840 nm to 860 nm. Each well layer was a lamina having a thickness of 7.5 nm and consisting of GaAs, while each barrier layer was a lamina having a thickness of 5 nm and consisting of Al_{0.30}Ga_{0.70}As.

In addition, in the present embodiment a double-heterostructure epitaxial wafer, differing in being furnished with an active layer composed only of well layers whose emission wavelength was 870 nm and having a thickness of 0.5 μm, was grown as a separate epitaxial wafer for infrared LEDs.

As far as the respective grown epitaxial wafers are concerned, the epitaxial wafers were each manufactured without removing the GaAs substrate. Next, onto the contact layer 23, an electrode consisting of AuZn, and onto the n-type GaAs substrate 13, an electrode consisting of AuGe were respectively formed by a vapor-deposition technique. Infrared LEDs were thereby obtained.

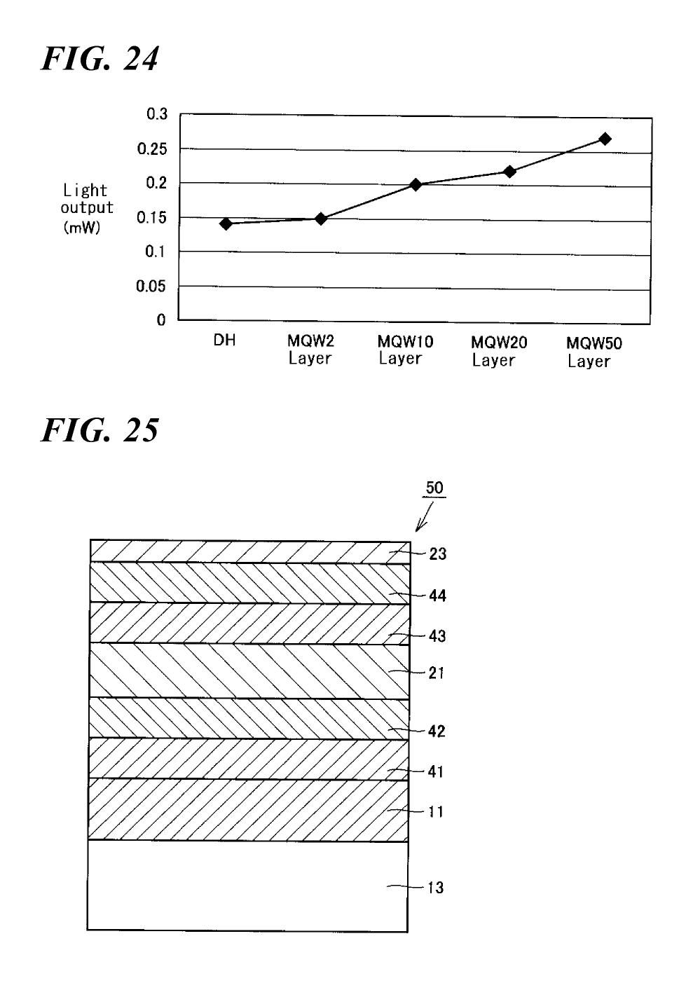

The light output of each infrared LED when a current of 20 mA was passed through it was measured with a constant-current source and a photometric instrument (integrating sphere). The results are diagrammed in FIG. 24. It should be noted that “DH” along the horizontal axis in FIG. 24 signifies an LED having a double heterostructure, “MQW” signifies LEDs furnished with well layers and barrier layers in an active layer, and the number of layers signifies the laminae count of the well layers and of the barrier layers, respectively.

It was found that, as indicated in FIG. 24, compared with the LED having a double heterostructure, the LEDs furnished with an active layer having a multiquantum-well structure allowed the light output to be improved. In particular, it was understood that the LEDs with between ten and fifty well layers and barrier layers (both inclusive) led to dramatically improved light output.

Herein, in the present embodiment, the AlₓGa₍₁₋ₓ₎As layers 11 were manufactured by organometallic vapor-phase epitaxy, but OMVPE requires an extraordinary amount of time in order to grow the AlₓGa₍₁₋ₓ₎As layers 11 if their thickness is to be as great as in cases such as Embodiment 1. Excluding this point, the characteristics of the formed infrared LEDs are the same as those of infrared LEDs of the present invention for which liquid-phase epitaxy and organometallic vapor-phase epitaxy were utilized, and thus are applicable to infrared LEDs of the present invention. It should be noted that in implementations in which the AlₓGa₍₁₋ₓ₎As layer 11 thickness is large, utilizing LPE demonstrates the effect of making it possible to shorten the time needed in order to grow the AlₓGa₍₁₋ₓ₎As layer 11.

In addition, in the present embodiment, as still another epitaxial wafer for infrared LEDs, epitaxial wafers of multiquantum-well structure (MQW), differing only in that their emission wavelength was 940 nm and in being furnished with an active layer containing well layers having InGaAs in the well laminae, were grown. With the InGaAs of the well laminae, the thickness was 2 nm to 10 nm and the amount fraction of 1n consisted of 0.1 to 0.3. Meanwhile, the barrier layers were consisted of Al_{0.30}Ga_{0.70}As.

Onto these epitaxial wafers also, in the same way as described above, electrodes were formed to create infrared LEDs. As to these infrared LEDs as well, the light output power was characterized in the same way as described above, with the result that light output power whose emission wavelength was 940 nm was obtained.

Here, with respect to the barrier layers it has been confirmed by experimentation that even if they are anywhere from GaAs_{0.90}P_{0.10} to Al_{0.30}Ga_{0.70}As_{0.90}P_{0.10} they will have similar results. Further, the fact that the amount fraction of 1n and the amount fraction of P are adjustable at will has been confirmed by experimentation.

From the foregoing, it could be confirmed that in instances in which the emission wavelength was between 840 nm and 890 nm (both inclusive), the MQW with the well laminae being GaAs was utilized as the active layer, while in instances in which the emission wavelength was between 860 nm and 890 nm (both inclusive), a double heterostructure (DH) constituted by GaAs was applicable. In addition, it could be confirmed that in instances in which the emission wavelength was between 850 nm and 1100 nm (both inclusive), it was possible to create active layers from well layers constituted by InGaAs.

### Embodiment 4

In the present embodiment, the effective range of thickness of the AlₓGa₍₁₋ₓ₎As layer 11 in infrared-LED epitaxial wafers was investigated.

In the present embodiment, five different samples, indicated in FIG. 25, of epitaxial wafers 50 were grown in which only the thickness of the AlₓGa₍₁₋ₓ₎As layer 11 was varied.

Specifically, GaAs substrates 13 were prepared (Step S1). Next, by liquid-phase epitaxy, AlₓGa₍₁₋ₓ₎As layers 11 having thicknesses of 2 μm, 10 μm, 20 μm, 100 μm, and 140 μm, and constituted from p-type Al_{0.35}Ga_{0.65}As doped with Zn were respectively formed (Step S2). The LPE growth temperature at which the AlₓGa₍₁₋ₓ₎As layers 11 were grown was 780° C., and the growth rate was an average 4 μm/h. Next, using hydrochloric acid and sulfuric acid, the major surface 11a of the AlₓGa₍₁₋ₓ₎As layers 11 was washed (Step S3). Subsequently, the major surface 11a of the AlₓGa₍₁₋ₓ₎As layers 11 was polished by means of chemical-mechanical planarization (Step S4). The major surface 11a of the AlₓGa₍₁₋ₓ₎As layers 11 was then washed using ammonia and hydrogen peroxide (Step S5). Next, by organometallic vapor-phase epitaxy, a p-type cladding layer 41, an undoped guide layer 42, an active layer 21, an undoped guide layer 43, a n-type cladding layer 44, and an n-type contact layer 23 were grown, in that order (Step S6). The OMVPE growth temperature for growing these layers was 750° C., while the growth rate was 1 to 2 μm/h. It should be noted that the thicknesses and the materials (apart from the dopants) for the p-type cladding layer 41, the undoped guide layer 42, the undoped guide layer 43, the n-type cladding layer 44, and the n-type contact layer 23 were made the same as in Embodiment 3. Also, active layers 21 having twenty laminae each of well layers and barrier layers were grown. Each well layer was a lamina having a thickness of 7.5 nm and consisting of GaAs, while each barrier layer was a lamina having a thickness of 5 nm and consisting of Al_{0.30}Ga_{0.70}As.

Next, the GaAs substrate 13 was removed (Step S7). Infrared-LED epitaxial wafers furnished with AlₓGa₍₁₋ₓ₎As layers having five different thicknesses were thereby manufactured.

Next, onto the contact layer 23, an electrode consisting of AuGe, and onto the rear face 11b of the AlₓGa₍₁₋ₓ₎As layer 11, an electrode consisting of AuZn were respectively formed by a vapor-deposition technique. Infrared LEDs were thereby manufactured.

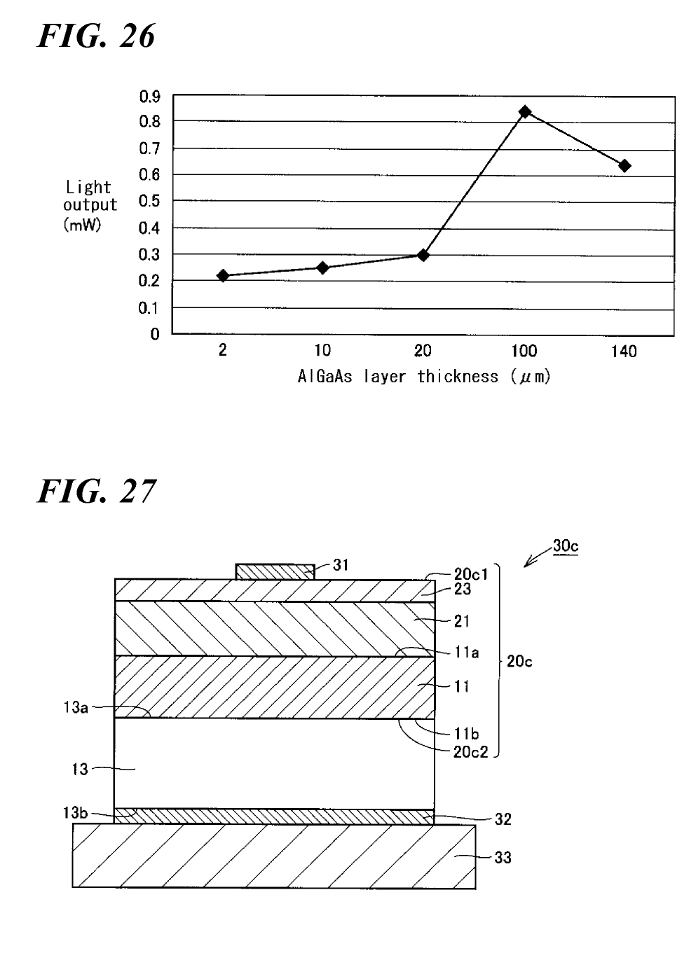

The light output of each of the infrared LEDs was measured in the same way as in Embodiment 3. The results are diagrammed in FIG. 26.

As indicated in FIG. 26, infrared LEDs furnished with an AlₓGa₍₁₋ₓ₎As layer 11 having a thickness greater than 20 μm but not more than 140 μm made it possible to improve light output significantly, while infrared LEDs furnished with an AlₓGa₍₁₋ₓ₎As layer 11 having a thickness between 100 μm and 140 μm (both inclusive) made possible extraordinary improvement in light output.

Now, at less than 20 μm, the fact that effectiveness from the GaAs 13 substrate having been removed was not seen is, from luminescent image observations, believed to be because there was hardly any change in the extent of the emission surface area. That is because on account of the low mobility with an Zn-doped p-type AlₓGa₍₁₋ₓ₎As layer 11, current does not diffuse. This can be remedied by having it be a Te-doped n-type AlₓGa₍₁₋ₓ₎As layer 11 to raise the mobility. In below described Embodiment 5, making the layers Te-doped was seen to broaden the luminescent image, improving the light output.

### Embodiment 5

In the present embodiment, the effectiveness of dispersion into the active layer being low by means of infrared LEDs of the present invention was investigated.

### Sample 1

A Sample 1 infrared-LED epitaxial wafer was manufactured as follows. Specifically, at first a GaAs substrate 13 was prepared (Step S1). Next, by liquid-phase epitaxy, a Te-doped AlₓGa₍₁₋ₓ₎As layer 11 having a thickness of 20 μm and constituted from n-type Al_{0.35}Ga₍₁₋ₓ₎As was grown (Step S2). Next, using hydrochloric acid and sulfuric acid, the major surface 11a of the AlₓGa₍₁₋ₓ₎As layer 11 was washed (Step S3). Subsequently, the major surface 11a of the AlₓGa₍₁₋ₓ₎As layer 11 was polished by means of chemical-mechanical planarization (Step S4). The major surface 11a of the AlₓGa₍₁₋ₓ₎As layer 11 was then washed using ammonia and hydrogen peroxide (Step S5). Next, by organometallic vapor-phase epitaxy, an Si-doped n-type cladding layer 41, an undoped guide layer 42, an active layer 21, an undoped guide layer 43, a Zn-doped p-type cladding layer 44, and a p-type contact layer 23 were grown, in that order (Step S6), as illustrated in FIG. 25. It should be noted that the thicknesses and the materials apart from the dopants for the n-type cladding layer 41, the undoped guide layer 42, the undoped guide layer 43, and the p-type cladding layer 44 were made the same as in Embodiment 3. Also, active layers 21 having twenty laminae each of well layers and barrier layers were grown. Each well layer was a lamina having a thickness of 7.5 nm and consisting of GaAs, while each barrier layer was a lamina having a thickness of 5 nm and consisting of Al_{0.30}Ga_{0.70}As. It should also be noted that the growth temperatures and growth rates in the LPE and OMVPE were made the same as in Embodiment 4.

Next, the GaAs substrate 13 was removed (Step S7). Sample 1 infrared-LED epitaxial wafers were thereby manufactured.

Next, onto the p-contact layer 23, an electrode consisting of AuZn, and onto the bottom of the AlₓGa₍₁₋ₓ₎As layer 11, an electrode consisting of AuGe were respectively formed by a vapor-deposition technique (Step S11). Infrared LEDs were thereby manufactured.

### Sample 2

For Sample 2, to begin with a GaAs substrate 13 was prepared (Step S1). Next, by organometallic vapor-phase epitaxy, a p-type cladding layer 44, an undoped guide layer 43, an active layer 21, an undoped guide layer 42, and an n-type cladding layer 41 were grown, in that order, in the same manner as with Sample 1. Next, an AlₓGa₍₁₋ₓ₎As layer 11 was formed by liquid-phase epitaxy. The thickness of and material constituting the AlₓGa₍₁₋ₓ₎As layer 11 was made the same as with Sample 1.

Next, likewise as with Sample 1, the GaAs substrate 13 was removed, to manufacture Sample 2 infrared-LED epitaxial wafers.

Next, electrodes wee formed onto the front and back sides of the epitaxial wafer in the same manner as with Sample 1, whereby Sample 2 infrared LEDs were thereby manufactured

Measurement Means

The Zn diffusion length in, and the light output from, Samples 1 and 2 were measured. Specifically, the Zn concentration in the interface between the active layer and the guide layers was characterized by secondary ion mass spectrometry, and further, the position in the active layer where the Zn concentration fell to 1/10 or less was measured by SIMS, and the distance into the active layer from the interface between the active layer and the guide layers was taken as the Zn diffusion length. In addition, the light output was measured in the same way as in Embodiment 3. The results are set forth in Table II below.

TABLE II

| | Zn diffusion | Zn max. conc. within | Light output |
|---|---|---|---|
| | length (μm) | active layer (cm⁻³) | (mW) |
| Pres. invent. ex. | 0 | 6.0 × 10¹⁵ | 1.3 |
| Comp. ex. | 0.3 | 6.0 × 10¹⁷ | 0.62 |

Measurement Results

As indicated in Table II, with Sample 1, in which the active layer was grown by OMVPE after the AlₓGa₍₁₋ₓ₎As layer 11 had been grown by LPE, the Zn doped into the AlₓGa₍₁₋ₓ₎As layer 11, formed ahead of the active layer, could be prevented from diffusing into the active layer, and the Zn concentration within the active layer 21 could be reduced. As a result, the light output from the Sample 1 infrared LED could be dramatically improved over that from Sample 2.

From the foregoing, it was confirmed that in accordance with the present invention, forming the active-layer-incorporating epitaxial layer (Step S7) after the AlₓGa₍₁₋ₓ₎As layer 11 has been formed by LPE (Step S2) enables the light output to be improved.

### Embodiment 6

In the present embodiment, the effectiveness with which an infrared LED of 900 nm or greater wavelength could be prepared was examined. In the present embodiment, an infrared LED was manufactured in the same way as with the infrared LED manufacturing method of Embodiment 4, while differing only in terms of the active layer 21. Specifically, in the present embodiment, an active layer 21 having 20 laminae of, respectively, well layers each having a thickness of 6 nm and being made of In_{0.12}Ga_{0.88}As and barrier layers each having a thickness of 12 nm and being made of GaAs_{0.9}P_{0.1} was grown.

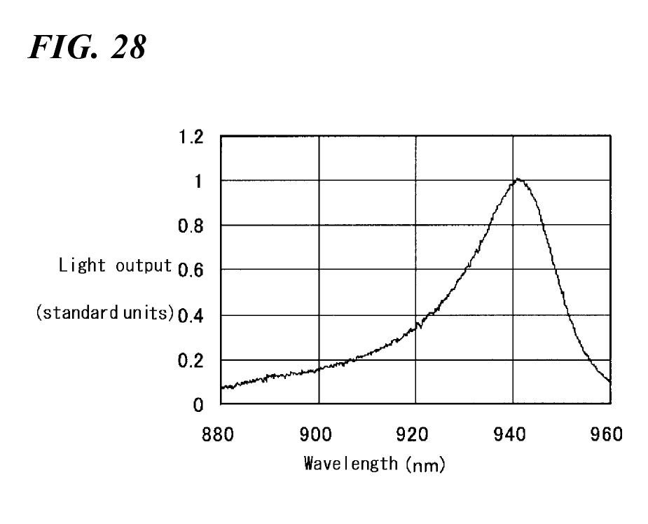

The emission spectrum for this infrared LED was characterized. The result is graphed in FIG. 28. As indicated in FIG. 28, it was confirmed that an infrared LED of 940 nm emission wavelength could be manufactured.

### Embodiment 7

In the present embodiment, the conditions for an epitaxial wafer to be utilized in an infrared LED of 900 nm or greater emission wavelength were examined.

### Present Invention Examples 1 through 4

The infrared LEDs of Present Invention Examples 1 through 4 were manufactured in the same way as with the infrared LED manufacturing method of Embodiment 6, while differing only in terms of the AlₓGa₍₁₋ₓ₎As layer 11 and the active layer 21. Specifically, the average amount fraction of Al in the AlₓGa₍₁₋ₓ₎As layers 11 was made as set forth in Table III below. The Al amount fraction in the major surface and in the rear face of the AlₓGa₍₁₋ₓ₎As layers 11 was, to cite single instances in the order (rear face, major surface): for 0.05, (0.10, 0.01); for 0.15, (0.25, 0.05); for 0.25, (0.35, 0.15); and for 0.35, (0.40, 0.30). The average Al amount fraction and the amount fraction in the (rear face, major surface) are, however, adjustable at will. Here, the amount fraction of Al monotonically decreased heading from the rear face to the major surface of the AlₓGa₍₁₋ₓ₎As layers 11. And for the active layer 21 in this case, an active layer 21 having 5 laminae of, respectively, well layers each made of InGaAs and barrier layers each made of GaAs was grown. The infrared LEDs had an emission wavelength of 890 nm.

### Present Invention Examples 5 through 8

The infrared LEDs of Present Invention Examples 5 through 8 were manufactured in the same way as with the infrared LED manufacturing method of Present Invention Examples 1 through 4, while differing in that the emission wavelength was 940 nm.

### Comparative Examples 1 and 2

The infrared LEDs of Comparative Examples 1 and 2 were manufactured in the same way as with the infrared LEDs of Present Invention Examples 1 through 4 and Present Invention Examples 5 through 8, respectively, while differing in not being furnished with an AlₓGa₍₁₋ₓ₎As layer 11. That is, an AlₓGa₍₁₋ₓ₎As layer 11 was not formed, nor was the GaAs substrate removed.

### Measurement Method

Lattice relaxation with regard to the infrared LEDs of Present Invention Examples 1 through 8 and Comparative Examples 1 and 2 was determined. The lattice relaxation was carried out by photoluminescence spectroscopy, x-ray diffraction, and visual inspection of the surface. When the lattice-relaxed epitaxial wafers were fabricated into infrared LEDs, they were verified as such by dark lines. Also, the light output power of the infrared LEDs of Present Invention Examples 1 through 8 and Comparative Examples 1 and 2 was measured in the same way as in Embodiment 3. The results are set forth in Table III below.

TABLE III

| | Substrate | | Active layer | | | | Light |
|---|---|---|---|---|---|---|---|
| | | Al amt. | | Number | Lattice | Emission | output |
| | Material | fract. | Composition | laminae | relax. | wvlng. | power |
| Pres. Inv. Ex. 1 | AlGaAs | 0.05 | InGaAs/GaAs | 5 | Absent | 890 nm | 5 mW |
| Pres. Inv. Ex. 2 | AlGaAs | 0.15 | InGaAs/GaAs | 5 | Absent | 890 nm | 6 mW |
| Pres. Inv. Ex. 3 | AlGaAs | 0.25 | InGaAs/GaAs | 5 | Absent | 890 nm | 6 mW |
| Pres. Inv. Ex. 4 | AlGaAs | 0.35 | InGaAs/GaAs | 5 | Absent | 890 nm | 6 mW |
| Comp. Ex. 1 | GaAs | — | InGaAs/GaAs | 5 | Absent | 890 nm | 1.5 mW |
| Pres. Inv. Ex. 5 | AlGaAs | 0.05 | InGaAs/GaAs | 5 | Pres. | 940 nm | 2 mW |
| Pres. Inv. Ex. 6 | AlGaAs | 0.15 | InGaAs/GaAs | 5 | Pres. | 940 nm | 3 mW |
| Pres. Inv. Ex. 7 | AlGaAs | 0.25 | InGaAs/GaAs | 5 | Pres. | 940 nm | 3.5 mW |
| Pres. Inv. Ex. 8 | AlGaAs | 0.35 | InGaAs/GaAs | 5 | Pres. | 940 nm | 3.5 mW |
| Comp. Ex. 2 | GaAs | — | InGaAs/GaAs | 5 | Absent | 940 nm | 1.5 mW |

As indicated in Table III, in the infrared LEDs whose emission wavelength was 890 nm, there was no lattice relaxation (lattice misalignment), regardless of whether the substrate was a GaAs substrate or an AlₓGa₍₁₋ₓ₎As layer. Likewise, in the infrared LED of Comparative Example 2, made from a GaAs substrate alone, there was no lattice relaxation, despite the emission wavelength being 940 nm. In the infrared LEDs of Present Invention Examples 5 through 8, however, which were furnished with an AlₓGa₍₁₋ₓ₎As layer 11 as an AlₓGa₍₁₋ₓ₎As substrate and which had an emission wavelength of 940 nm, there was lattice relaxation. Accordingly, with infrared LEDs furnished with an AlₓGa₍₁₋ₓ₎As layer 11 as an AlₓGa₍₁₋ₓ₎As substrate, whereas the output power of the infrared LEDs in which there was no lattice relaxation was 5 mW to 6 mW, the output power of the infrared LEDs in which there was lattice relaxation was a low 2 to 3.5 mW, wherein it was understood that inconsistency within the surface of the same wafer is significant. More particularly, the measurement inconsistency was in wafers having a 2- to 4-inch φ wafer diameter.

From this fact it was understood that technology that can be applied on GaAs substrates cannot be applied to epitaxial wafers that are utilized in infrared LEDs whose emission wavelength is 900 nm or greater.

Therein, the present inventors devoted research, as discussed below, to investigating the conditions whereby lattice relaxation is curbed in epitaxial wafers that are utilized in infrared LEDs whose emission wavelength is 900 nm or greater.

Specifically, in the following way, infrared LEDs of Present Invention Examples 9 through 24 and Comparative Examples 3 through 6, in which the emission wavelength was 940 nm, were manufactured.

### Present Invention Examples 9 through 12

The infrared LEDs of Present Invention Examples 9 through 12 basically were manufactured in the same way as with the infrared LEDs of Present Invention Examples 5 through 8, while differing in that the number respectively of well layers and of barrier layers each was made three laminae. The In amount fraction in the well layers was 0.12.

### Present Invention Examples 13 through 16

The infrared LEDs of Present Invention Examples 13 through 16 basically were manufactured in the same way as with the infrared LEDs of Present Invention Examples 5 through 8, while differing in having the barrier layers be GaAsP, and making the number of well layers and of barrier layers three laminae respectively. The P amount fraction in the barrier layers was 0.10.

### Present Invention Examples 17 through 20

The infrared LEDs of Present Invention Examples 17 through 20 basically were manufactured in the same way as with the infrared LEDs of Present Invention Examples 13 through 16, while differing in that the number of well layers and of barrier layers was made ten laminae respectively.

### Present Invention Examples 21 through 24

The infrared LEDs of Present Invention Examples 21 through 24 basically were manufactured in the same way as with the infrared LEDs of Present Invention Examples 5 through 8, while differing in having the barrier layers be AlGaAsP, and making the number of well layers and of barrier layers twenty laminae respectively. The P amount fraction in the barrier layers was 0.10.

### Comparative Examples 3 through 6

The infrared LEDs of Comparative Example 3 basically were manufactured in the same way as with the infrared LEDs of, respectively, Present Invention Examples 9 through 12, Present Invention Examples 13 through 16, Present Invention Examples 17 through 20, and Present Invention Examples 21 through 24, while differing in that a GaAs substrate not furnished with an AlₓGa₍₁₋ₓ₎As layer as an AlₓGa₍₁₋ₓ₎As substrate was employed.

### Measurement Method

In the same manner as with the methods explained above, the lattice relaxation and light output power were determined, the results are set forth in Table IV below.

TABLE IV

| | Substrate | | Active layer | | | Light |
|---|---|---|---|---|---|---|
| | | Al amt. | | Number | Lattice | output |
| | Material | fract. | Composition | laminae | relax. | power |
| Pres. Inv. Ex. 9 | AlGaAs | 0.05 | InGaAs/GaAs | 3 | Absent | 6 mW |
| Pres. Inv. Ex. 10 | AlGaAs | 0.15 | InGaAs/GaAs | 3 | Absent | 6 mW |
| Pres. Inv. Ex. 11 | AlGaAs | 0.25 | InGaAs/GaAs | 3 | Absent | 6 mW |
| Pres. Inv. Ex. 12 | AlGaAs | 0.35 | InGaAs/GaAs | 3 | Absent | 6 mW |
| Comp. Ex. 3 | GaAs | — | InGaAs/GaAs | 3 | Absent | 1.5 mW |
| Pres. Inv. Ex. 13 | AlGaAs | 0.05 | InGaAs/GaAsP | 3 | Absent | 6 mW |
| Pres. Inv. Ex. 14 | AlGaAs | 0.15 | InGaAs/GaAsP | 3 | Absent | 6 mW |
| Pres. Inv. Ex. 15 | AlGaAs | 0.25 | InGaAs/GaAsP | 3 | Absent | 6 mW |
| Pres. Inv. Ex. 16 | AlGaAs | 0.35 | InGaAs/GaAsP | 3 | Absent | 6 mW |
| Comp. Ex. 4 | GaAs | — | InGaAs/GaAsP | 3 | Absent | 1.5 mW |
| Pres. Inv. Ex. 17 | AlGaAs | 0.05 | InGaAs/GaAsP | 10 | Absent | 6 mW |
| Pres. Inv. Ex. 18 | AlGaAs | 0.15 | InGaAs/GaAsP | 10 | Absent | 6 mW |
| Pres. Inv. Ex. 19 | AlGaAs | 0.25 | InGaAs/GaAsP | 10 | Absent | 6 mW |
| Pres. Inv. Ex. 20 | AlGaAs | 0.35 | InGaAs/GaAsP | 10 | Absent | 6 mW |
| Comp. Ex. 5 | GaAs | — | InGaAs/GaAsP | 10 | Absent | 1.5 mW |
| Pres. Inv. Ex. 21 | AlGaAs | 0.05 | InGaAs/AlGaAsP | 20 | Absent | 6 mW |
| Pres. Inv. Ex. 22 | AlGaAs | 0.15 | InGaAs/AlGaAsP | 20 | Absent | 6 mW |
| Pres. Inv. Ex. 23 | AlGaAs | 0.25 | InGaAs/AlGaAsP | 20 | Absent | 6 mW |
| Pres. Inv. Ex. 24 | AlGaAs | 0.35 | InGaAs/AlGaAsP | 20 | Absent | 6 mW |
| Comp. Ex. 6 | GaAs | — | InGaAs/AlGaAsP | 20 | Absent | 1.5 mW |

### Measurement Results

As indicated in Table IV, with Present Invention Examples 9 through 12, which included InGaAs wherein the well layers within the active layer 21 contained In, and whose number of well layers was four laminae or fewer, lattice relaxation did not occur.

Likewise, with Present Invention Examples 13 through 24, which included either GaAsP or AlGaAsP wherein the barrier layers within the active layer contained P, and whose number of barrier layers was three laminae or more, lattice relaxation did not occur.

From the foregoing, according to the present embodiments, it was discovered that in epitaxial wafers utilized in infrared LEDs whose emission wavelength is 900 nm or greater, lattice misalignment could be controlled to a minimum in instances where the well layers within the active layer include a material containing In and the number of well layers is four or fewer laminae, and in instances where the barrier layers within the active layer include a material containing P, the number of barrier layers is three or more laminae.

The presently disclosed embodiments and implementation examples should in all respects be considered to be illustrative and not limiting. The scope of the present invention is set forth not by the foregoing description but by the scope of the patent claims, and is intended to include meanings equivalent to the scope of the patent claims and all modifications within the scope.

### REFERENCE SIGNS LIST

10a, 10b: AlₓGa₍₁₋ₓ₎As substrate; 11: AlₓGa₍₁₋ₓ₎As layer; 11a, 13a: major surface; 11b, 13b, 20c2, 21c: rear face; 13: GaAs substrate; 20a, 20b, 20c, 40, 50: epitaxial wafer; 20c1: surface; 21: active layer; 21a: well layers; 12b: barrier layers; 23: contact layer; 30a, 30b, 30c: LEDs; 31, 32: electrodes; 33: stem; 41, 44: cladding layers; 42, 43: undoped guiding layers.

1. An AlₓGa₍₁₋ₓ₎As substrate furnished with an AlₓGa₍₁₋ₓ₎As layer (0≦x≦1) having a major surface and, on the reverse side from the major surface, a rear face; the AlₓGa₍₁₋ₓ₎As substrate characterized in that
in the AlₓGa₍₁₋ₓ₎As layer, the amount fraction x of Al in the rear face is greater than the amount fraction x of Al in the major surface.

2. The AlₓGa₍₁₋ₓ₎As substrate set forth in claim 1, wherein:
the AlₓGa₍₁₋ₓ₎As layer contains a plurality of laminae; and
the amount fraction x of Al in each of the plural laminae monotonically decreases heading from the plane of the layer's rear-face side to the plane of its major-surface side.

3. The AlₓGa₍₁₋ₓ₎As substrate set forth in claim 1, further furnished with a GaAs substrate contacting the rear face of the AlₓGa₍₁₋ₓ₎As layer.

4. An epitaxial wafer for infrared LEDs, the wafer furnished with:
the AlₓGa₍₁₋ₓ₎As substrate set forth in claim 1; and
an epitaxial layer formed onto the major surface of the AlₓGa₍₁₋ₓ₎As layer, and including an active layer.

5. (canceled)

6. The infrared-LED epitaxial wafer set forth in claim 4, the epitaxial wafer being utilized in an infrared LED whose emission wavelength is 900 nm or greater, and wherein well layers within the active layer include a material containing indium, the number of well layers is four or fewer laminae, and the well layers are of InGaAs in which the amount fraction of indium is 0.05 or more.

7. (canceled)

8. The infrared-LED epitaxial wafer set forth in claim 4, the epitaxial wafer being utilized in an infrared LED whose emission wavelength is 900 nm or greater, and wherein barrier layers within the active layer include a material containing phosphorous, the number of barrier layers is three or more laminae, and the barrier layers are of either GaAsP or AlGaAsP in which the amount fraction of phosphorous is 0.05 or more.

9. (canceled)

10. An infrared LEDs furnished with:
the AlₓGa₍₁₋ₓ₎As substrate set forth in claim 1;
an epitaxial layer formed onto the major surface of the AlₓGa₍₁₋ₓ₎As layer, and including an active layer;
a first electrode formed on the surface of the epitaxial layer; and
a second electrode formed on the rear face of the AlₓGa₍₁₋ₓ₎As layer.

11. An infrared LED furnished with:
the AlₓGa₍₁₋ₓ₎As substrate set forth in claim 3;
an epitaxial layer formed onto the major surface of the AlₓGa₍₁₋ₓ₎As layer, and including an active layer;
a first electrode formed on the surface of the epitaxial layer; and
a second electrode formed on the rear face of the GaAs substrate.

12. A method of manufacturing an AlₓGa₍₁₋ₓ₎As substrate, the method provided with:
a step of preparing a GaAs substrate; and
a step of growing, by liquid-phase epitaxy, onto the GaAs substrate an AlₓGa₍₁₋ₓ₎As layer (0≦x≦1) having a major surface; characterized in that
in the AlₓGa₍₁₋ₓ₎As layer growing step, the AlₓGa₍₁₋ₓ₎As layer is grown with the amount fraction x of Al in the interface between the layer and the GaAs substrate being greater than the amount fraction x of Al in the major surface.

13. The AlₓGa₍₁₋ₓ₎As substrate manufacturing method set forth in claim 12, wherein in the AlₓGa₍₁₋ₓ₎As layer growing step, the AlₓGa₍₁₋ₓ₎As layer is grown containing a plurality of laminae in which the amount fraction x of Al monotonically decreases heading from the plane along the layer's interface with the GaAs substrate to the plane of the layer's major-surface side.

14. The AlₓGa₍₁₋ₓ₎As substrate manufacturing method set forth in claim 12, further provided with a step of removing the GaAs substrate.

15. A method of manufacturing an epitaxial wafer for infrared LEDs, the method provided with:
a step of manufacturing the AlₓGa₍₁₋ₓ₎As substrate by the AlₓGa₍₁₋ₓ₎As substrate manufacturing method set forth in claim 12; and
a step of forming onto the major surface of the AlₓGa₍₁₋ₓ₎As layer, by at least organometallic vapor-phase epitaxy or molecular beam epitaxy, an epitaxial layer containing an active layer.

16. (canceled)

17. The infrared-LED epitaxial wafer manufacturing method set forth in claim 15, being a method of manufacturing an epitaxial wafer utilized in an infrared LED whose emission wavelength is 900 nm or greater, and wherein well layers within the active layer include a material containing indium, the number of well layers is four or fewer laminae, and the well layers are of InGaAs in which the amount fraction of indium is 0.05 or more.

18. (canceled)

19. The infrared-LED epitaxial wafer manufacturing method set forth in claim 15, being a method of manufacturing an epitaxial wafer utilized in an infrared LED whose emission wavelength is 900 nm or greater, and wherein barrier layers within the active layer include a material containing phosphorous, the number of barrier layers is three or more laminae, and the barrier layers are of either GaAsP or AlGaAsP in which the amount fraction of phosphorous is 0.05 or more.

20. (canceled)

21. An infrared-LED manufacturing method provided with:
a step of manufacturing an AlₓGa₍₁₋ₓ₎As substrate by the AlₓGa₍₁₋ₓ₎As substrate manufacturing method set forth in claim 12;
a step of forming onto the major surface of the AlₓGa₍₁₋ₓ₎As layer, by either organometallic vapor-phase epitaxy or molecular beam epitaxy, an epitaxial layer containing an active layer to obtain an epitaxial wafer;
a step of forming a first electrode on the surface of the epitaxial wafer; and
a step of forming a second electrode on the rear face of the GaAs substrate.

22. An infrared-LED manufacturing method provided with:
a step of manufacturing an AlₓGa₍₁₋ₓ₎As substrate by the AlₓGa₍₁₋ₓ₎As substrate manufacturing method set forth in claim 14;
a step of forming onto the major surface of the AlₓGa₍₁₋ₓ₎As layer, by either organometallic vapor-phase epitaxy or molecular beam epitaxy, an epitaxial layer containing an active layer to obtain an epitaxial wafer;
a step of forming a first electrode on the surface of the epitaxial wafer; and
a step of forming a second electrode on the rear face of the AlₓGa₍₁₋ₓ₎As layer.

23. An epitaxial wafer for infrared LEDs, the wafer furnished with:
the AlₓGa₍₁₋ₓ₎As substrate set forth in claim 3; and
an epitaxial layer formed onto the major surface of the AlₓGa₍₁₋ₓ₎As layer, and including an active layer.

24. The infrared-LED epitaxial wafer set forth in claim 23, the epitaxial wafer being utilized in an infrared LED whose emission wavelength is 900 nm or greater, and wherein well layers within the active layer include a material containing indium, the number of well layers is four or fewer laminae, and the well layers are of InGaAs in which the amount fraction of indium is 0.05 or more.

25. The infrared-LED epitaxial wafer set forth in claim 23, the epitaxial wafer being utilized in an infrared LED whose emission wavelength is 900 nm or greater, and wherein barrier layers within the active layer include a material containing phosphorous, the number of barrier layers is three or more laminae, and the barrier layers are of either GaAsP or AlGaAsP in which the amount fraction of phosphorous is 0.05 or more.
